(19) United States
(12) Patent Application Publication
(10) Pub. No.: US 2023/0116959 A1
(43) Pub. Date: Apr. 20, 2023

(54) ENERGY STORAGE SYSTEM

(71) Applicant: LG ELECTRONICS INC., Seoul (KR)

(72) Inventors: Seungmin LEE, Seoul (KR); Eunchul PARK, Seoul (KR)

(73) Assignee: LG ELECTRONICS INC., Seoul (KR)

(21) Appl. No.: 17/555,229

(22) Filed: Dec. 17, 2021

(30) Foreign Application Priority Data
Oct. 14, 2021 (KR) 10-2021-0136639

(51) Int. Cl. H02J 7/00; H01M 10/48; H01M 10/42; H01M 10/44

(52) U.S. Cl. CPC H02J 7/007194; H01M 10/425; H01M 10/443; H01M 10/486; H02J 7/0013; H02J 7/00032; H02J 7/0048; H02J 7/00712; H01M 2010/4271

(57) ABSTRACT

An energy storage system of the present disclosure includes: a battery configured to store received electrical energy in a form of direct current, or to output the stored electrical energy; and a battery management system configured to control the battery, wherein the battery management system includes: a sensing unit comprising a sensor for measuring temperature of the battery; a memory in which a derating table for charging and a derating table for discharging are stored; and a microcomputer unit configured to control C-rate based on the temperature of the battery and the derating table for charging when charging the battery, and to control the C-rate based on the temperature of the battery and the derating table for discharging when discharging the battery.

### CROSS-REFERENCE TO RELATED APPLICATION

Pursuant to 35 U.S.C. § 119(a), this application claims the benefit of earlier filing date and right of priority to Korean Pat. Application No. 10-2021-0136639, filed on Oct. 14, 2021, the contents of which are hereby incorporated by reference herein in its entirety.

### BACKGROUND OF THE INVENTION

### 1. Field of the Invention

The present disclosure relates to an energy storage system, and more particularly, to a battery-based energy storage system and an operating method thereof.

### 2. Description of the Related Art

An energy storage system is a system that stores or charges external power, and outputs or discharges stored power to the outside. To this end, the energy storage system includes a battery, and a power conditioning system is used for supplying power to the battery or outputting power from the battery.

Since the energy storage system has the possibility of accidents such as explosion, ignition, and gas emission, various technologies have been proposed to improve safety. For example, Korean Pat. Publication No. 2006-0059680 discloses a circuit for protecting circuits and battery cells from short circuit and overvoltage, and Korean Pat. Publication No. 2018-0103212 discloses a battery and battery protection circuit.

If the battery is used continuously while the temperature of the battery rises to a high temperature, the battery life will decrease. In addition, when the temperature of the battery is used at a low temperature, the internal resistance increases, so that the efficiency is lowered and high output is difficult.

Therefore, when charging or discharging the battery, it is desirable to operate in a safe temperature range in terms of efficiency and safety.

### SUMMARY OF THE INVENTION

An object of the present disclosure is to provide an energy storage system capable of operating in a safe temperature range for a battery.

Another object of the present disclosure is to provide an energy storage system capable of improving battery life while maintaining an appropriate temperature state.

Another object of the present disclosure is to provide an energy storage system capable of achieving high output while maintaining a stable state.

Another object of the present disclosure is to provide an energy storage system that enhanced safety by a multi-safety design.

Another object of the present disclosure is to provide an energy storage system capable of effectively dissipating heat.

In order to achieve the above object, the energy storage system according to embodiments of the present disclosure may improve safety and efficiency by controlling the battery to operate in a safe temperature range.

In order to achieve the above object, the energy storage system according to embodiments of the present disclosure may improve safety through a multi-safety design.

In order to achieve the above object, in the energy storage system according to embodiments of the present disclosure, a main circuit configuration may be separated to protect a control circuit from a problem inside the battery pack.

In accordance with an aspect of the present disclosure, the energy storage system includes: a battery configured to store received electrical energy in a form of direct current, or to output the stored electrical energy; and a battery management system configured to control the battery, wherein the battery management system includes: a sensing unit including a sensor for measuring temperature of the battery; a memory in which a derating table for charging and a derating table for discharging are stored; and a microcomputer unit configured to control C-rate based on the temperature of the battery and the derating table for charging when charging the battery, and to control the C-rate based on the temperature of the battery and the derating table for discharging when discharging the battery.

The microcomputer unit may calculate a state of charge (SOC) of the battery, and control charging and discharging of the battery based on the calculated state of charge, the temperature of the battery, the derating table for charging, and the derating table for discharging.

The derating table for charging and the derating table for discharging may be configured of C-rate values corresponding to the temperature of the battery and the state of charge of the battery.

The battery includes a plurality of battery packs, and a cooling fan is disposed in one side of each battery pack.

The cooling fan is turned on when the temperature of the battery is higher than or equal to an overheating reference value.

When the temperature of the battery is equal to or lower than a stable temperature reference value, the cooling fan is turned off, if the cooling fan is in a turn-on state.

The energy storage system according to an embodiment of the present disclosure further includes a power conditioning system for transmitting outside air temperature data to the battery management system, and when the temperature of the battery is lower than or equal to the outside air temperature, the cooling fan is turned off, if the cooling fan is in a turn-on state.

The energy storage system according to an embodiment of the present disclosure further includes a casing forming a space in which the power conditioning system and the plurality of battery packs are disposed.

In the energy storage system according to an embodiment of the present disclosure, the battery includes a plurality of battery cells, the sensor for measuring the temperature of the battery is a thermistor disposed in an outer circumference of at least one of the plurality of battery cells, and the temperature of the battery is based on at least one of temperature data sensed by the thermistor.

The battery includes a plurality of battery packs respectively including a plurality of battery cells, wherein the battery management system includes: battery pack circuit boards configured to be disposed in each of the plurality of battery packs, and to acquire state information of the plurality of battery cells included in each battery pack; and a main circuit board configured to be connected to the battery pack circuit boards by a communication line, and to receive state information acquired from each battery pack from the battery pack circuit boards.

The microcomputer unit and the memory are mounted in the main circuit board.

The sensor for measuring the temperature of the battery is a thermistor disposed in an outer circumference of at least one of the plurality of battery cells, wherein the thermistor included in each of the plurality of battery packs and the battery pack circuit board are connected by wire.

The plurality of battery packs may be connected in series by a power line, and the power line may be connected to the main circuit board.

The derating table for discharging includes more C-rate levels than the derating table for charging.

The microcomputer unit lowers the C-rate, if the temperature and the state of charge of the battery are higher than or equal to a charging reference value, during the charging of battery, and lowers the C-rate, if the state of charge of the battery is less than or equal to a discharge reference value, during the discharging of battery.

An energy storage system according to an embodiment of the present disclosure includes: a battery configured to store received electrical energy in a form of direct current, or to output the stored electrical energy; and a battery management system configured to control the battery, wherein the battery includes a plurality of battery packs respectively including a plurality of battery cells and a cooling fan, wherein the battery management system includes: a sensing unit including a sensor for measuring temperature of the battery; and a microcomputer unit configured to change a C-rate according to a temperature change of the battery, and turns on the cooling fan when the temperature of the battery is equal to or higher than an overheating reference value.

In addition, the battery management system further includes a memory in which a derating table for charging and a derating table for discharging are stored, wherein the microcomputer unit calculates a state of charge (SOC) of the battery, and controls charging and discharging of the battery based on the calculated state of charge, the temperature of the battery, the derating table for charging, and the derating table for discharging.

In addition, the energy storage system according to an embodiment of the present disclosure further includes a power conditioning system for transmitting outside air temperature data to the battery management system, wherein when the temperature of the battery is equal to or lower than the outside air temperature, the cooling fan is turned off, if the cooling fan is in a turn-on state.

In addition, when the temperature of the battery is equal to or lower than a stable temperature reference value, the cooling fan is turned off, if the cooling fan is in a turn-on state.

In addition, the sensor for measuring the temperature of the battery is a thermistor disposed in an outer circumference of at least one of the plurality of battery cells, wherein the temperature of the battery is based on at least one of temperature data sensed by the thermistor.

The battery includes a plurality of battery packs respectively including a plurality of battery cells, wherein the battery management system includes: battery pack circuit boards configured to be disposed in each of the plurality of battery packs, and to acquire state information of the plurality of battery cells included in each battery pack; and a main circuit board configured to be connected to the battery pack circuit boards by a communication line, and to receive state information acquired from each battery pack from the battery pack circuit boards.

### BRIEF DESCRIPTION OF THE DRAWINGS

The above and other objects, features and advantages of the present disclosure will be more apparent from the following detailed description in conjunction with the accompanying drawings, in which:

The above and other objects, features and advantages of the present disclosure will be more apparent from the following detailed description in conjunction with the accompanying drawings, in which:

FIGS. 1A and 1B are conceptual diagrams of an energy supply system including an energy storage system according to an embodiment of the present disclosure;

FIG. 2 is a conceptual diagram of a home energy service system including an energy storage system according to an embodiment of the present disclosure;

FIGS. 3A and 3B are diagrams illustrating an energy storage system installation type according to an embodiment of the present disclosure;

FIG. 4 is a conceptual diagram of a home energy service system including an energy storage system according to an embodiment of the present disclosure;

FIG. 5 is an exploded perspective view of an energy storage system including a plurality of battery packs according to an embodiment of the present disclosure;

FIG. 6 is a front view of an energy storage system in a state in which a door is removed;

FIG. 7 is a cross-sectional view of one side of FIG. 6;

FIG. 8 is a perspective view of a battery pack according to an embodiment of the present disclosure;

FIG. 9 is an exploded view of a battery pack according to an embodiment of the present disclosure;

FIG. 10 is a perspective view of a battery module according to an embodiment of the present disclosure;

FIG. 11 is an exploded view of a battery module according to an embodiment of the present disclosure;

FIG. 12 is a front view of a battery module according to an embodiment of the present disclosure;

FIG. 13 is an exploded perspective view of a battery module and a sensing substrate according to an embodiment of the present disclosure;

FIG. 14 is a perspective of a battery module and a battery pack circuit substrate according to an embodiment of the present disclosure;

FIG. 15A is one side view in a coupled state of FIG. 14;

FIG. 15B is the other side view in a coupled state of FIG. 14;

FIG. 16 is a diagram for explaining a connection between the battery pack and a battery management system according to an embodiment of the present disclosure;

FIG. 17 is a cross-sectional view of a battery pack according to an embodiment of the present disclosure;

FIG. 18 is a cross-sectional view for explaining a disposition of battery cells inside a battery pack;

FIG. 19 is a perspective view of a thermistor according to an embodiment of the present disclosure;

FIG. 20 is a diagram for explaining an internal resistance of the battery;

FIG. 21 is a block diagram of an energy storage system according to an embodiment of the present disclosure;

FIG. 22 is a flowchart illustrating an operating method of an energy storage system according to an embodiment of the present disclosure; and

FIGS. 23 and 24 are diagrams for explaining an operating method of an energy storage system according to an embodiment of the present disclosure.

### DETAILED DESCRIPTION OF THE PREFERRED EMBODIMENTS

Hereinafter, embodiments of the present disclosure will be described in detail with reference to the accompanying drawings. However, it is obvious that the present disclosure is not limited to these embodiments and may be modified in various forms.

In the drawings, in order to clearly and briefly describe the present disclosure, the illustration of parts irrelevant to the description is omitted, and the same reference numerals are used for the same or extremely similar parts throughout the specification.

Hereinafter, the suffixes “module” and “unit” of elements herein are used for convenience of description and thus may be used interchangeably and do not have any distinguishable meanings or functions. Thus, the “module” and the “unit” may be interchangeably used.

It will be understood that, although the terms “first”, “second”, etc. may be used herein to describe various elements, these elements should not be limited by these terms. These terms are only used to distinguish one element from another element.

The top U, bottom D, left Le, right Ri, front F, and rear R used in drawings are used to describe a battery pack and an energy storage system including the battery pack, and may be set differently according to standard.

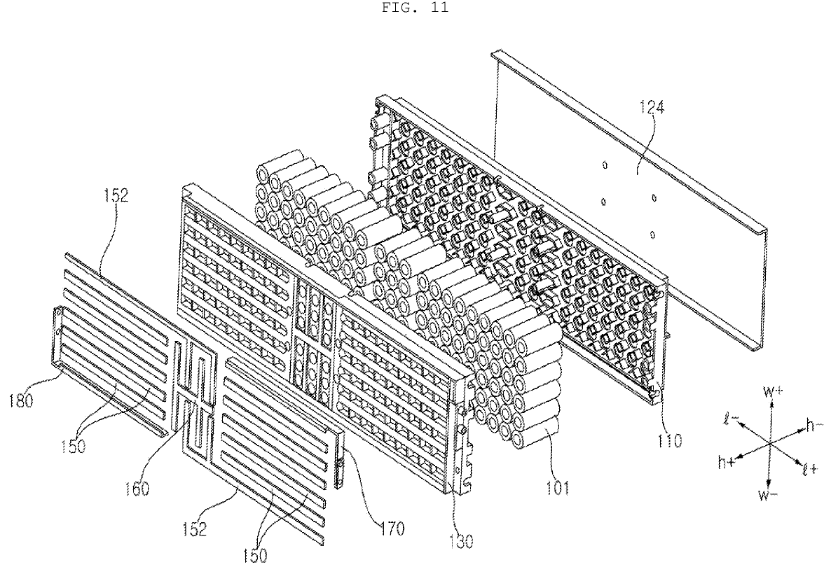

The height direction (h+, h-), length direction (l+, l-), and width direction (w+, w-) of the battery module used in FIGS. 10 to 13 are used to describe the battery module, and may be set differently according to standard.

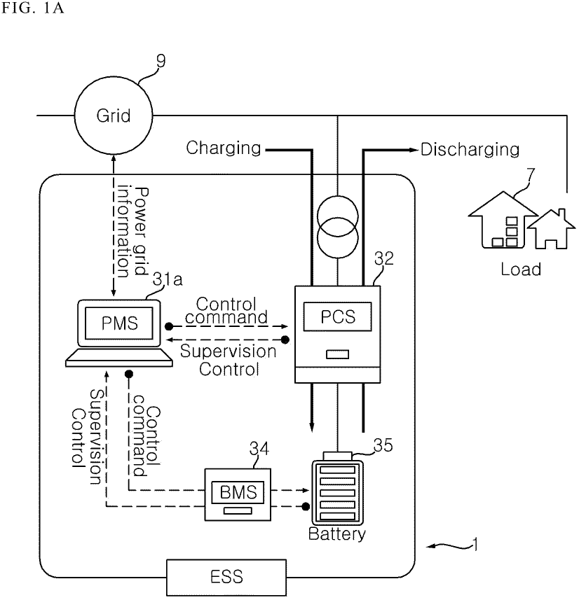

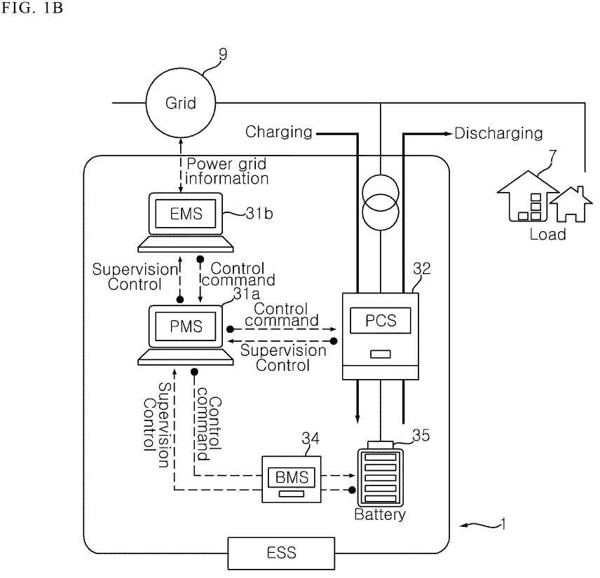

FIGS. 1A and 1B are conceptual diagrams of an energy supply system including an energy storage system according to an embodiment of the present disclosure.

Referring to FIGS. 1A and 1B, the energy supply system includes a battery 35-based energy storage system 1 in which electrical energy is stored, a load 7 that is a power demander, and a grid 9 provided as an external power supply source.

The energy storage system 1 includes a battery 35 that stores (charges) the electric energy received from the grid 9, or the like in the form of direct current (DC) or outputs (discharges) the stored electric energy to the grid 9, or the like, a power conditioning system 32 (PCS) for converting electrical characteristics (e.g. AC/DC interconversion, frequency, voltage) for charging or discharging the battery 35, and a battery management system 34 (BMS) that monitors and manages information such as current, voltage, and temperature of the battery 35.

The grid 9 may include a power generation facility for generating electric power, a transmission line, and the like. The load 7 may include a home appliance such as a refrigerator, a washing machine, an air conditioner, a TV, a robot cleaner, and a robot, a mobile electronic device such as a vehicle and a drone, and the like, as a consumer that consumes power.

The energy storage system 1 may store power from an external in the battery 35 and then output power to the external. For example, the energy storage system 1 may receive DC power or AC power from the external, store it in the battery 35, and then output the DC power or AC power to the external.

Meanwhile, since the battery 35 mainly stores DC power, the energy storage system 1 may receive DC power or convert the received AC power to DC power and store it in the battery 35, and may convert the DC power stored in the battery 35, and may supply to the grid 9 or the load 7.

At this time, the power conditioning system 32 in the energy storage system 1 may perform power conversion and voltage-charge the battery 35, or may supply the DC power stored in the battery 35 to the grid 9 or the load 7.

The energy storage system 1 may charge the battery 35 based on power supplied from the system and discharge the battery 35 when necessary. For example, the electric energy stored in the battery 35 may be supplied to the load 7 in an emergency such as a power outage, or at a time, date, or season when the electric energy supplied from the grid 9 is expensive.

The energy storage system 1 has the advantage of being able to improve the safety and convenience of new renewable energy generation by storing electric energy generated from a new renewable energy source such as sunlight, and to be used as an emergency power source. In addition, when the energy storage system 1 is used, it is possible to perform load leveling for a load having large fluctuations in time and season, and to save energy consumption and cost.

The battery management system 34 may measure the temperature, current, voltage, state of charge, and the like of the battery 35, and monitor the state of the battery 35. In addition, the battery management system 34 may control and manage the operating environment of the battery 35 to be optimized based on the state information of the battery 35.

Meanwhile, the energy storage system 1 may include a power management system 31a (PMS) that controls the power conditioning system 32.

The power management system 31a may perform a function of monitoring and controlling the states of the battery 35 and the power conditioning system 32. The power management system 31a may be a controller that controls the overall operation of the energy storage system 1.

The power conditioning system 32 may control power distribution of the battery 35 according to a control command of the power management system 31a. The power conditioning system 32 may convert power according to the grid 9, a power generation means such as photovoltaic light, and the connection state of the battery 35 and the load 7.

Meanwhile, the power management system 31a may receive state information of the battery 35 from the battery management system 34. A control command may be transmitted to the power conditioning system 32 and the battery management system 34.

The power management system 31a may include a communication means such as a Wi-Fi communication module, and a memory. Various information necessary for the operation of the energy storage system 1 may be stored in the memory. In some embodiments, the power management system 31a may include a plurality of switches and control a power supply path.

The power management system 31a and/or the battery management system 34 may calculate the SOC of the battery 35 using various well-known SOC calculation methods such as a coulomb counting method and a method of calculating a state of charge (SOC) based on an open circuit voltage (OCV). The battery 35 may overheat and irreversibly operate when the state of charge exceeds a maximum state of charge. Similarly, when the state of charge is less than or equal to the minimum state of charge, the battery may deteriorate and become unrecoverable. The power management system 31a and/or the battery management system 34 may monitor the internal temperature, the state of charge of the battery 35, and the like in real time to control an optimal usage area and maximum input/output power.

The power management system 31a may operate under the control of an energy management system (EMS) 31b, which is an upper controller. The power management system 31a may control the energy storage system 1 by receiving a command from the energy management system 31b, and may transmit the state of the energy storage system 1 to the energy management system 31b. The energy management system 31b may be provided in the energy storage system 1 or may be provided in an upper system of the energy storage system 1.

The energy management system 31b may receive information such as charge information, power usage, and environmental information, and may control the energy storage system 1 according to the energy production, storage, and consumption patterns of user. The energy management system 31b may be provided as an operating system for monitoring and controlling the power management system 31a.

The controller for controlling the overall operation of the energy storage system 1 may include the power management system 31a and/or the energy management system 31b. In some embodiments, one of the power management system 31a and the energy management system 31b may also perform the other function. In addition, the power management system 31a and the energy management system 31b may be integrated into one controller to be integrally provided.

Meanwhile, the installation capacity of the energy storage system 1 varies according to the customer’s installation condition, and a plurality of the power conditioning systems 32 and the batteries 35 may be connected to expand to a required capacity.

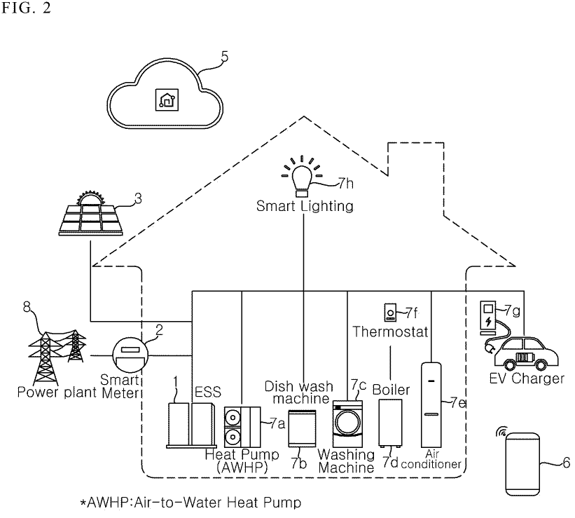

The energy storage system 1 may be connected to at least one generating plant (refer to 3 of FIG. 2) separately from the grid 9. A generating plant 3 may include a wind generating plant that outputs DC power, a hydroelectric generating plant that outputs DC power using hydroelectric power, a tidal generating plant that outputs DC power using tidal power, thermal generating plant that outputs DC power using heat such as geothermal heat, or the like. Hereinafter, for convenience of description, the photovoltaic plant will be mainly described as the generating plant 3.

FIG. 2 is a conceptual diagram of a home energy service system including an energy storage system according to an embodiment of the present disclosure.

The home energy service system according to an embodiment of the present disclosure may include the energy storage system 1, and may be configured as a cloud 5-based intelligent energy service platform for integrated energy service management.

Referring to FIG. 2, the home energy service system is mainly implemented in a home, and may manage the supply, consumption, and storage of energy (power) in the home.

The energy storage system 1 may be connected to a grid 9 such as a power plant 8, a generating plant such as a photovoltaic generator 3, a plurality of loads 7a to 7g, and sensors (not shown) to configure a home energy service system.

The loads 7a to 7g may be a heat pump 7a, a dishwasher 7b, a washing machine 7c, a boiler 7d, an air conditioner 7e, a thermostat 7f, an electric vehicle (EV) charger 7g, a smart lighting 7h, and the like.

The home energy service system may include other loads in addition to the smart devices illustrated in FIG. 2. For example, the home energy service system may include several lights in addition to the smart lighting 7h having one or more communication modules. In addition, the home energy service system may include a home appliance that does not include a communication module.

Some of the loads 7a to 7g are set as essential loads, so that power may be supplied from the energy storage system 1 when a power outage occurs. For example, a refrigerator and at least some lighting devices may be set as essential loads that require backup in case of power failure.

Meanwhile, the energy storage system 1 can communicate with the devices 7a to 7g, and the sensors through a short-range wireless communication module. For example, the short-range wireless communication module may be at least one of Bluetooth, Wi-Fi, and Zigbee. In addition, the energy storage system 1, the devices 7a to 7g, and the sensors may be connected to an Internet network.

The energy management system 31b may communicate with the energy storage system 1, the devices 7a to 7g, the sensors, and the cloud 5 through an Internet network, and a short-range wireless communication.

The energy management system 31b and/or the cloud 5 may transmit information received from the energy storage device 1, the devices 7a to 7g, and sensors and information determined using the received information to the terminal 6. The terminal 6 may be implemented as a smart phone, a PC, a notebook computer, a tablet PC, or the like. In some embodiments, an application for controlling the operation of the home energy service system may be installed and executed in the terminal 6.

The home energy service system may include a meter 2. The meter 2 may be provided between the power grid 9 such as the power plant 8 and the energy storage system 1. The meter 2 may measure the amount of power supplied to the home from the power plant 8 and consumed. In addition, the meter 2 may be provided inside the energy storage system 1. The meter 2 may measure the amount of power discharged from the energy storage system 1. The amount of power discharged from the energy storage system 1 may include the amount of power supplied (sold) from the energy storage system 1 to the power grid 9, and the amount of power supplied from the energy storage system 1 to the devices 7a to 7g.

The energy storage system 1 may store the power supplied from the photovoltaic generator 2 and/or the power plant 8, or the residual power remaining after the supplied power is consumed.

Meanwhile, the meter 2 may be implemented of a smart meter. The smart meter may include a communication module for transmitting information related to power usage to the cloud 5 and/or the energy management system 31b.

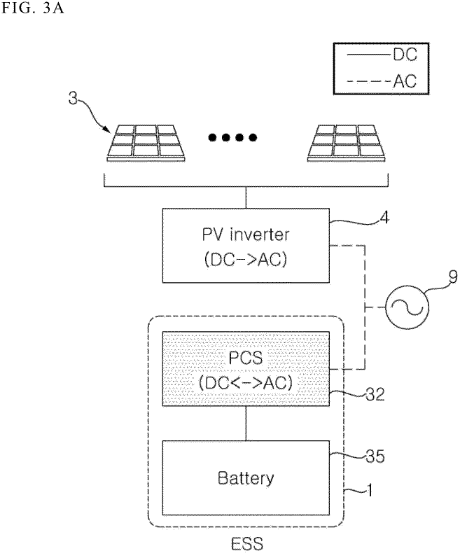

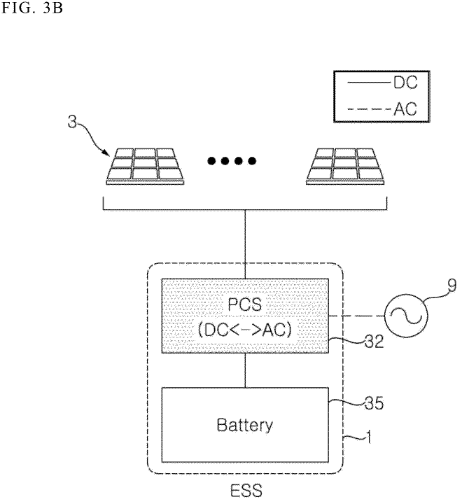

FIGS. 3A and 3B are diagrams illustrating an energy storage system installation type according to an embodiment of the present disclosure.

The home energy storage system 1 may be divided into an AC-coupled ESS (see FIG. 3A) and a DC-coupled ESS (see FIG. 3B) according to an installation type.

The photovoltaic plant includes a photovoltaic panel 3. Depending on the type of photovoltaic installation, the photovoltaic plant may include a photovoltaic panel 3 and a photovoltaic PV inverter 4 that converts DC power supplied from the photovoltaic panel 3 into AC power (see FIG. 3A). Thus, it is possible to implement the system more economically, as the energy storage system 1 independent of the existing grid 9 can be used.

In addition, according to an embodiment, the power conditioning system 32 of the energy storage system 1 and the PV inverter 4 may be implemented as an integrated power conversion device (see FIG. 3B). In this case, the DC power output from the photovoltaic panel 3 is input to the power conditioning system 32. The DC power may be transmitted to and stored in the battery 35. In addition, the power conditioning system 32 may convert DC power into AC power and supply to the grid 9. Accordingly, a more efficient system implementation can be achieved.

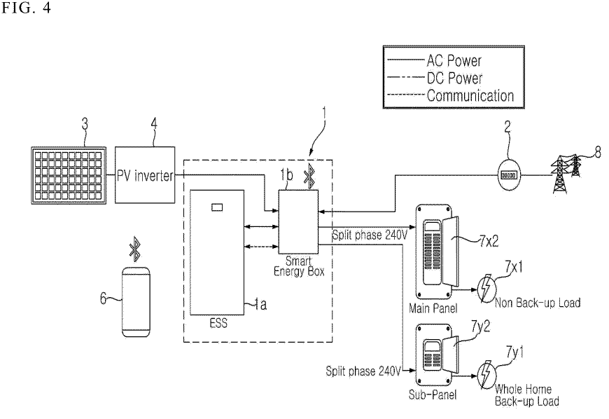

FIG. 4 is a conceptual diagram of a home energy service system including an energy storage system according to an embodiment of the present disclosure.

Referring to FIG. 4, the energy storage system 1 may be connected to the grid 9 such as the power plant 8, the power plant such as the photovoltaic generator 3, and a plurality of loads 7x1 and 7y1.

Electrical energy generated by the photovoltaic generator 3 may be converted in the PV inverter 4 and supplied to the grid 9, the energy storage system 1, and the loads 7x1 and 7y1. As described with reference to FIGS. 3, according to the type of installation, the electrical energy generated by the photovoltaic generator 3 may be converted in the energy storage system 1, and supplied to the grid 9, the energy storage system 1, and the loads 7x1, 7y1.

Meanwhile, the energy storage system 1 is provided with one or more wireless communication modules, and may communicate with the terminal 6. The user may monitor and control the state of the energy storage system 1 and the home energy service system through the terminal 6. In addition, the home energy service system may provide a cloud 5 based service. The user may communicate with the cloud 5 through the terminal 6 regardless of location and monitor and control the state of the home energy service system.

According to an embodiment of the present disclosure, the above-described battery 35, the battery management system 34, and the power conditioning system 32 may be disposed inside one casing 12. Since the battery 35, the battery management system 34, and the power conditioning system 32 integrated in one casing 12 can store and convert power, they may be referred to as an all-in-one energy storage system 1a.

In addition, in separate enclosures 1b outside the casing 12, a configuration for power distribution such as a power management system 31a, an auto transfer switch ATS, a smart meter, and a switch, and a communication module for communication with the terminal 6, the cloud 5, and the like may be disposed. A configuration in which configurations related to power distribution and management are integrated in one enclosure 1 may be referred to as a smart energy box 1b.

The above-described power management system 31a may be received in the smart energy box 1b. A controller for controlling the overall power supply connection of the energy storage system 1 may be disposed in the smart energy box 1b. The controller may be the above mentioned power management system 31a.

In addition, switches are received in the smart energy box 1b to control the connection state of the connected grid power source 8, 9, the photovoltaic generator 3, the battery 35 of all-in-one energy storage system 1a, and loads 7x1, 7y1. The loads 7x1, 7y1 may be connected to the smart energy box 1b through the load panel 7x2, 7y2.

Meanwhile, the smart energy box 1b is connected to the grid power source 8, 9 and the photovoltaic generator 3. In addition, when a power failure occurs in the system 8, 9, the auto transfer switch ATS that is switched so that the electric energy which is produced by the photovoltaic generator 3 or stored in the battery 35 is supplied to a certain load 7y1 may be disposed in the smart energy box 1b.

Alternatively, the power management system 31a may perform an auto transfer switch ATS function. For example, when a power failure occurs in the system 8, 9, the power management system 31a may control a switch such as a relay so that the electrical energy that is produced by the photovoltaic generator 3 or stored in the battery 35 is transmitted to a certain load 7y1.

Meanwhile, a current sensor, a smart meter, or the like may be disposed in each current supply path. Electric energy of the electricity produced through the energy storage system 1 and the photovoltaic generator 3 may be measured and managed by a smart meter (at least a current sensor).

The energy storage system 1 according to an embodiment of the present disclosure includes at least an all-in-one energy storage system 1a. In addition, the energy storage system 1 according to an embodiment of the present disclosure includes the all-in-one energy storage system 1a and the smart energy box 1b, thereby providing an integrated service that can simply and efficiently perform storage, supply, distribution, communication, and control of power.

Meanwhile, the energy storage system 1 according to an embodiment of the present disclosure may operate in a plurality of operation modes. In a PV self consumption mode, photovoltaic generation power is first used in the load, and the remaining power is stored in the energy storage system 1. For example, when more power is generated than the amount of power used by the loads 7x1 and 7y1 in the photovoltaic generator 3 during the day, the battery 35 is charged.

In a charge/discharge mode based on a rate system, four time zones may be set and input, the battery 35 may be discharged during a time period when the electric rate is expensive, and the battery 35 may be charged during a time period when the electric rate is cheap. The energy storage system 1 may help a user to save electric rate in the charge/discharge mode based on a rate system.

A backup-only mode is a mode for emergency situations such as power outages, and can operate, with the highest priority, such that when a typhoon is expected by a weather forecast or there is a possibility of other power outages, the battery 35 may be charged up to a maximum and supplied to an essential load 7y1 in an emergency.

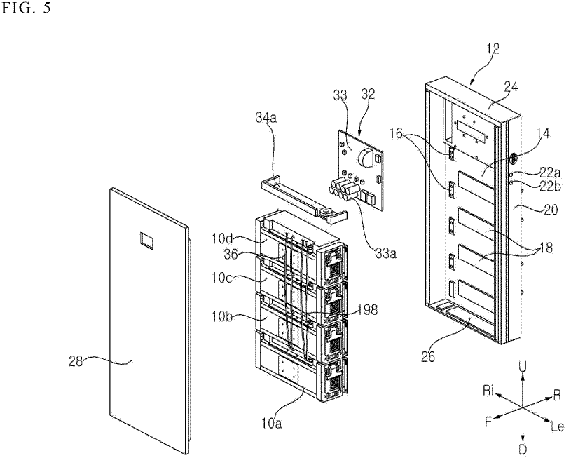

The energy storage system 1 of the present disclosure will be described with reference to FIGS. 5 to 7. More particularly, detailed structures of the all-in-one energy storage system 1a are disclosed.

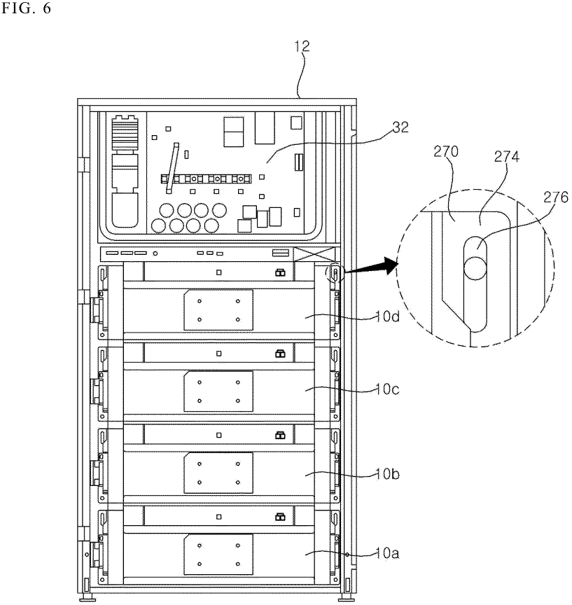

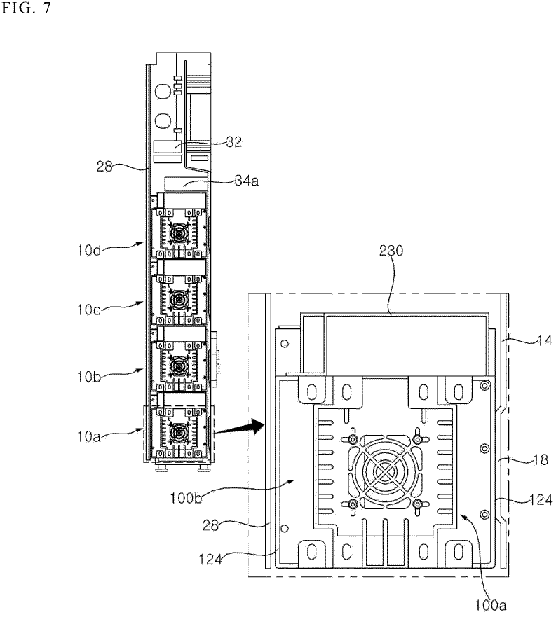

FIG. 5 is an exploded perspective view of an energy storage system including a plurality of battery packs according to an embodiment of the present disclosure, FIG. 6 is a front view of an energy storage system in a state in which a door is removed, FIG. 7 is a cross-sectional view of one side of FIG. 6.

Referring to FIG. 5, the energy storage system 1 includes at least one battery pack 10, a casing 12 forming a space in which at least one battery pack 10 is disposed, a door 28 for opening and closing the front surface of the casing 12, a power conditioning system 32 (PCS) which is disposed inside the casing 12 and converts the characteristics of electricity so as to charge or discharge a battery, and a battery management system (BMS) that monitors information such as current, voltage, and temperature of the battery cell 101.

The casing 12 may have an open front shape. The casing 12 may include a casing rear wall 14 covering the rear, a pair of casing side walls 20 extending to the front from both side ends of the casing rear wall 14, a casing top wall 24 extending to the front from the upper end of the casing rear wall 14, and a casing base 26 extending to the front from the lower end of the casing rear wall 14. The casing rear wall 14 includes a pack fastening portion 16 formed to be fastened with the battery pack 10 and a contact plate 18 protruding to the front to contact the heat dissipation plate 124 of the battery pack 10.

Referring to FIG. 5, the contact plate 18 may be disposed to protrude to the front from the casing rear wall 14. The contact plate 18 may be disposed to contact one side of the heat dissipation plate 124. Accordingly, heat emitted from the plurality of battery cells 101 disposed inside the battery pack 10 may be radiated to the outside through the heat dissipation plate 124 and the contact plate 18.

A switch 22a, 22b for turning on/off the power of the energy storage system 1 may be disposed in one of the pair of casing sidewalls 20. In the present disclosure, a first switch 22a and a second switch 22b are disposed to enhance the safety of the power supply or the safety of the operation of the energy storage system 1.

The power conditioning system 32 may include a circuit substrate 33 and an insulated gate bipolar transistor (IGBT) that is disposed in one side of the circuit substrate 33 and performs power conversion.

The battery monitoring system may include a battery pack circuit substrate 220 disposed in each of the plurality of battery packs 10a, 10b, 10c, 10d, and a main circuit substrate 34a which is disposed inside the casing 12 and connected to a plurality of battery pack circuit substrates 220 through a communication line 36.

The main circuit substrate 34a may be connected to the battery pack circuit substrate 220 disposed in each of the plurality of battery packs 10a, 10b, 10c, and 10d by the communication line 36. The main circuit substrate 34a may be connected to a power line 198 extending from the battery pack 10.

At least one battery pack 10a, 10b, 10c, and 10d may be disposed inside the casing 12. A plurality of battery packs 10a, 10b, 10c, and 10d are disposed inside the casing 12. The plurality of battery packs 10a, 10b, 10c, and 10d may be disposed in the vertical direction.

The plurality of battery packs 10a, 10b, 10c, and 10d may be disposed such that the upper end and lower end of each side bracket 250 contact each other. At this time, each of the battery packs 10a, 10b, 10c, and 10d disposed vertically is disposed such that the battery module 100a, 100b and the top cover 230 do not contact each other.

Each of the plurality of battery packs 10 is fixedly disposed in the casing 12. Each of the plurality of battery packs 10a, 10b, 10c, and 10d is fastened to the pack fastening portion 16 disposed in the casing rear wall 14. That is, the fixing bracket 270 of each of the plurality of battery packs 10a, 10b, 10c, and 10d is fastened to the pack fastening portion 16. The pack fastening portion 16 may be disposed to protrude to the front from the casing rear wall 14 like the contact plate 18.

The contact plate 18 may be disposed to protrude to the front from the casing rear wall 14. Accordingly, the contact plate 18 may be disposed to be in contact with one heat dissipation plate 124 included in the battery pack 10.

One battery pack 10 includes two battery modules 100a and 100b. Accordingly, two heat dissipation plates 124 are disposed in one battery pack 10. One heat dissipation plate 124 included in the battery pack 10 is disposed to face the casing rear wall 14, and the other heat dissipation plate 124 is disposed to face the door 28.

One heat dissipation plate 124 is disposed to contact the contact plate 18 disposed in the casing rear wall 14, and the other heat dissipation plate 124 is disposed to be spaced apart from the door 28. The other heat dissipation plate 124 may be cooled by air flowing inside the casing 12.

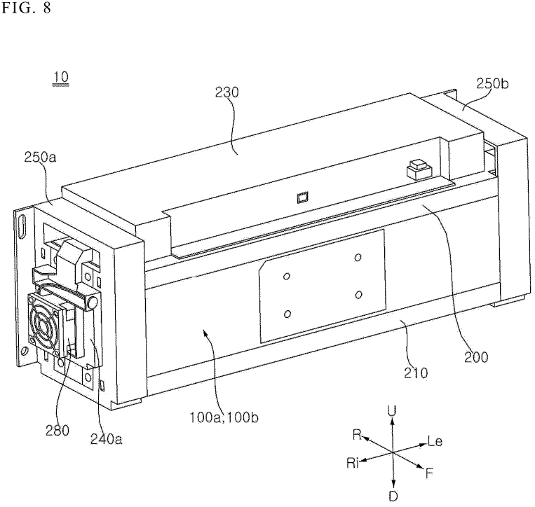

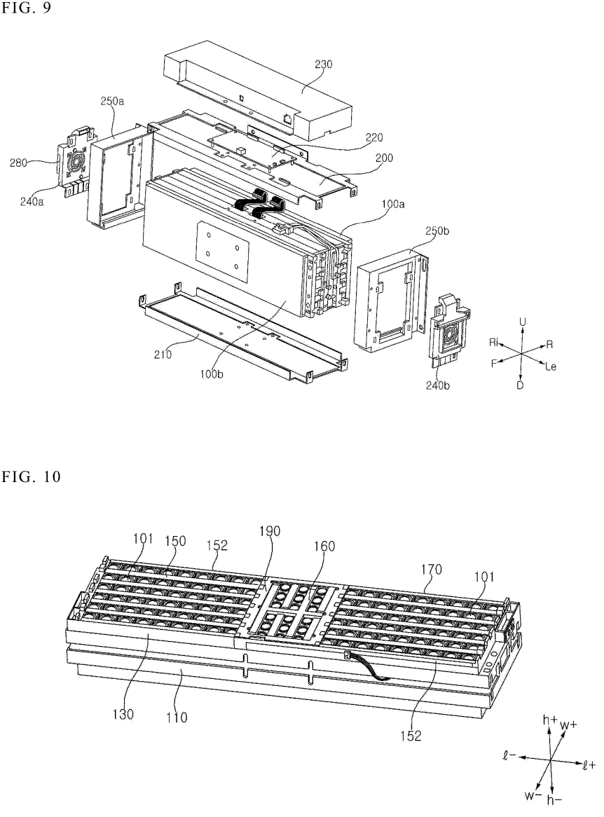

FIG. 8 is a perspective view of a battery pack according to an embodiment of the present disclosure, and FIG. 9 is an exploded view of a battery pack according to an embodiment of the present disclosure.

The energy storage system of the present disclosure may include a battery pack 10 in which a plurality of battery cells 101 are connected in series and in parallel. The energy storage system may include a plurality of battery packs 10a, 10b, 10c, and 10d (refer to FIG. 5).

First, a configuration of one battery pack 10 will be described with reference to FIGS. 8 to 9. The battery pack 10 includes at least one battery module 100a, 100b to which a plurality of battery cells 101 are connected in series and parallel, an upper fixing bracket 200 which is disposed in an upper portion of the battery module 100a, 100b and fixes the disposition of the battery module 100a, 100b, a lower fixing bracket 210 which is disposed in a lower portion of the battery module 100 and fixes the disposition of the battery modules 100a and 100b, a pair of side brackets 250a, 250b which are disposed in both side surfaces of the battery module 100a, 100b and fixes the disposition of the battery module 100a, 100b, a pair of side covers 240a, 240b which are disposed in both side surfaces of the battery module 100a, 100b, and in which a cooling hole 242a is formed, a cooling fan 280 which is disposed in one side surface of the battery module 100a, 100b and forms an air flow inside the battery module 100a, 100b, a battery pack circuit substrate 220 which is disposed in the upper side of the upper fixing bracket 200 and collects sensing information of the battery module 100a, 100b, and a top cover 230 which is disposed in the upper side of the upper fixing bracket 200 and covers the upper side of the battery pack circuit substrate 220.

The battery pack 10 includes at least one battery module 100a, 100b. Referring to FIG. 2, the battery pack 10 of the present disclosure includes a battery module assembly 100 configured of two battery modules 100a, 100b which are electrically connected to each other and physically fixed. The battery module assembly 100 includes a first battery module 100a and a second battery module 100b disposed to face each other.

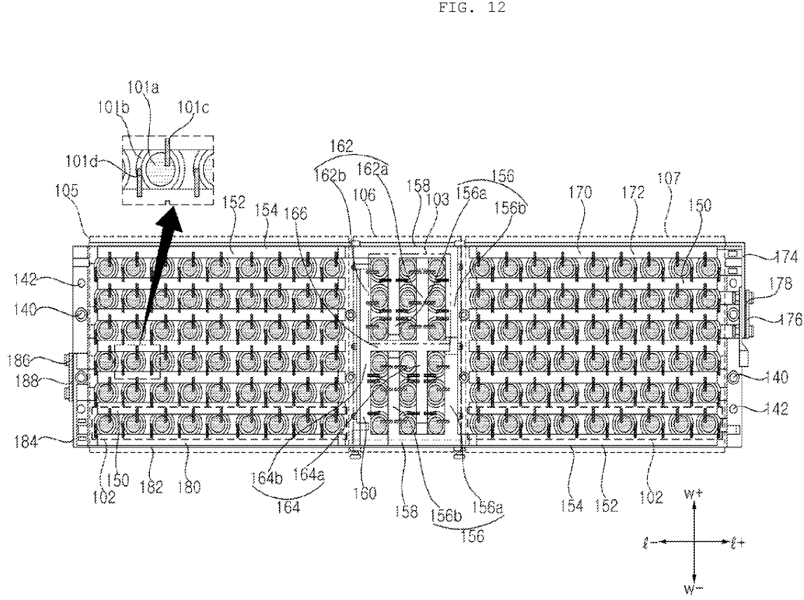

FIG. 10 is a perspective view of a battery module according to an embodiment of the present disclosure and FIG. 11 is an exploded view of a battery module according to an embodiment of the present disclosure.

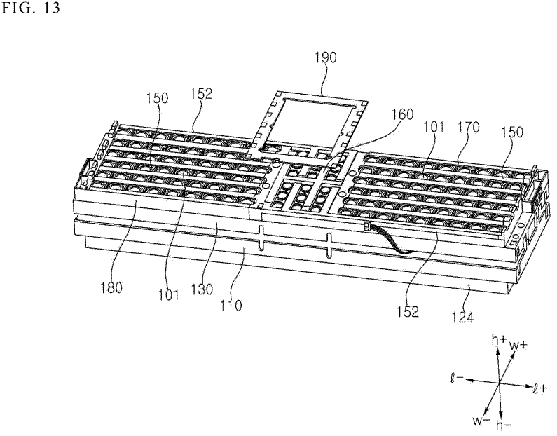

FIG. 12 is a front view of a battery module according to an embodiment of the present disclosure and FIG. 13 is an exploded perspective view of a battery module and a sensing substrate according to an embodiment of the present disclosure.

Hereinafter, the first battery module 100a of the present disclosure will be described with reference to FIGS. 10 to 13. The configuration and shape of the first battery module 100a described below may also be applied to the second battery module 100b.

The battery module described in FIGS. 10 to 13 may be described in a vertical direction based on the height direction (h+, h-) of the battery module. The battery module described in FIGS. 10 to 13 may be described in the left-right direction based on the length direction (l+, l-) of the battery module. The battery module described in FIGS. 10 to 13 may be described in the front-rear direction based on the width direction (w+, w-) of the battery module. The direction setting of the battery module used in FIGS. 10 to 13 may be different from the direction setting in a structure of the battery pack 10 described in other drawings. In the battery module described in FIGS. 10 to 13, the width direction (w+, w-) of the battery module may be described as a first direction, and the length direction (l+, l-) of the battery module may be described as a second direction.

The first battery module 100a includes a plurality of battery cells 101, a first frame 110 for fixing the lower portion of the plurality of battery cells 101, a second frame 130 for fixing the upper portion of the plurality of battery cells 101, a heat dissipation plate 124 which is disposed in the lower side of the first frame 110 and dissipates heat generated from the battery cell 101, a plurality of bus bars which are disposed in the upper side of the second frame 130 and electrically connect the plurality of battery cells 101, and a sensing substrate 190 which is disposed in the upper side of the second frame 130 and detects information of the plurality of battery cells 101.

The first frame 110 and the second frame 130 may fix the disposition of the plurality of battery cells 101. In the first frame 110 and the second frame 130, the plurality of battery cells 101 are disposed to be spaced apart from each other. Since the plurality of battery cells 101 are spaced apart from each other, air may flow into a space between the plurality of battery cells 101 by the operation of the cooling fan 280 described below.

The first frame 110 fixes the lower end of the battery cell 101. The first frame 110 includes a lower plate 112 having a plurality of battery cell holes 112a formed therein, a first fixing protrusion 114 which protrudes upward from the upper surface of the lower plate 112 and fixes the disposition of the battery cell 101, a pair of first sidewalls 116 which protrudes upward from both ends of the lower plate 112, and a pair of first end walls 118 which protrudes upward from both ends of the lower plate 112 and connects both ends of the pair of first side walls 116.

The pair of first sidewalls 116 may be disposed parallel to a first cell array 102 described below. The pair of first end walls 118 may be disposed perpendicular to the pair of first side walls 116.

Referring to FIG. 13, the first frame 110 includes a first fastening protrusion 120 protruding to be fastened to the second frame 130, and a module fastening protrusion 122 protruding to be fastened with the first frame 110 included in the second battery module 100b disposed adjacently. A frame screw 125 for fastening the second frame 130 and the first frame 110 is disposed in the first fastening protrusion 120. A module screw 194 for fastening the first battery module 100a and the second battery module 100b is disposed in the module fastening protrusion 122. The frame screw 125 fastens the second frame 130 and the first frame 110. The frame screw 125 may fix the disposition of the plurality of battery cells 101 by fastening the second frame 130 and the first frame 110.

The plurality of battery cells 101 are fixedly disposed in the second frame 130 and the first frame 110. A plurality of battery cells 101 are disposed in series and parallel. The plurality of battery cells 101 are fixedly disposed by a first fixing protrusion 114 of the first frame 110 and a second fixing protrusion 134 of the second frame 130.

Referring to FIG. 12, the plurality of battery cells 101 are spaced apart from each other in the length direction (l+, l-) and the width direction (w+, w-) of the battery module.

The plurality of battery cells 101 includes a cell array connected in parallel to one bus bar. The cell array may refer to a set electrically connected in parallel to one bus bar.

The first battery module 100a may include a plurality of cell arrays 102 and 103 electrically connected in series. The plurality of cell arrays 102 and 103 are electrically connected to each other in series. The first battery module 100a has a plurality of cell arrays 102 and 103 connected in series.

The plurality of cell arrays 102 and 103 may include a first cell array 102 in which a plurality of battery cells 101 are disposed in a straight line, and a second cell array 103 in which a plurality of cell array rows and columns are disposed.

The first battery module 100a may include a first cell array 102 in which a plurality of battery cells 101 are disposed in a straight line, and a second cell array 103 in which a plurality of rows and columns are disposed.

Referring to FIG. 12, in the first cell array 102, a plurality of battery cells 101 are disposed in the left and right side in the length direction (l+, l-) of the first battery module 100a. The plurality of first cell arrays 102 are disposed in the front and rear side in the width direction (w+, w-) of the first battery module 100a.

Referring to FIG. 12, the second cell array 103 includes a plurality of battery cells 101 spaced apart from each other in the width direction (w+, w-) and the length direction (l+, l-) of the first battery module 100a.

The first battery module 100a includes a first cell group 105 in which a plurality of first cell arrays 102 are disposed in parallel, and a second cell group 106 that includes at least one second cell array 103 and is disposed in one side of the first cell group 105.

The first battery module 100a includes a first cell group 105 in which a plurality of first cell arrays 102 are connected in series, and a third cell group 107 in which a plurality of first cell arrays 102 are connected in series, and which are spaced apart from the first cell group 105. The second cell group is disposed between the first cell group 105 and the third cell group 107.

In the first cell group 105, a plurality of first cell arrays 102 are connected in series. In the first cell group 105, a plurality of first cell arrays 102 are spaced apart from each other in the width direction of the battery module. The plurality of first cell arrays 102 included in the first cell group 105 are spaced apart in a direction perpendicular to the direction in which the plurality of battery cells 101 included in each of the first cell arrays 102 are disposed.

Referring to FIG. 12, nine battery cells 101 connected in parallel are disposed in each of the first cell array 102 and the second cell array 103. Referring to FIG. 12, in the first cell array 102, nine battery cells 101 are spaced apart from each other in the length direction of the battery module. In the second cell array 103, nine battery cells are spaced apart from each other in a plurality of rows and a plurality of columns. Referring to FIG. 12, in the second cell array 103, three battery cells 101 that are spaced apart from each other in the width direction of the battery module are spaced apart from each other in the length direction of the battery module. Here, the length direction (l+, l-) of the battery module may be set as a column direction, and the width direction (w+, w-) of the battery module may be set as a row direction.

Referring to FIG. 12, each of the first cell group 105 and the third cell group 107 is disposed such that six first cell arrays 102 are connected in series. In each of the first cell group 105 and the third cell group 107, six first cell arrays 102 are spaced apart from each other in the width direction of the battery module.

Referring to FIG. 12, the second cell group 106 includes two second cell arrays 103. The two second cell arrays 103 are spaced apart from each other in the width direction of the battery module. The two second cell arrays 103 are connected in parallel to each other. Each of the two second cell arrays 103 is disposed symmetrically with respect to the horizontal bar 166 of a third bus bar 160 described below.

The first battery module 100a includes a plurality of bus bars which are disposed between the plurality of battery cells 101, and electrically connect the plurality of battery cells 101. Each of the plurality of bus bars connects in parallel the plurality of battery cells included in a cell array disposed adjacent to each other. Each of the plurality of bus bars may connect in series two cell arrays disposed adjacent to each other.

The plurality of bus bars includes a first bus bar 150 connecting the two first cell arrays 102 in series, a second bus bar 152 connecting the first cell array 102 and the second cell array 103 in series, and a third bus bar 160 connecting the two second cell arrays 103 in series.

The plurality of bus bars include a fourth bus bar 170 connected to one first cell array 102 in series. The plurality of bus bars include a fourth bus bar 170 which is connected to one first cell array 102 in series and connected to other battery module 100b included in the same battery pack 10, and a fifth bus bar 180 which is connected to one first cell array 102 in series and connected to one battery module included in other battery pack 10. The fourth bus bar 170 and the fifth bus bar 180 may have the same shape.

The first bus bar 150 is disposed between two first cell arrays 102 spaced apart from each other in the length direction of the battery module. The first bus bar 150 connects in parallel a plurality of battery cells 101 included in one first cell array 102. The first bus bar 150 connects in series the two first cell arrays 102 disposed in the length direction (l+, l-) of the battery module.

Referring to FIG. 12, it is electrically connected to a positive terminal 101a of each of the battery cells 101 of the first cell array 102 which is disposed in the front in the width direction (w+, w-) of the battery module with respect to the first bus bar 150, and is electrically connected to a negative terminal 101b of each of the battery cells 101 of the first cell array 102 which is disposed in the rear in the width direction (w+, w-) of the battery module with respect to the first bus bar 150.

Referring to FIG. 12, in the battery cell 101, the positive terminal 101a and the negative terminal 101b are partitioned in the upper end thereof. In the battery cell 101, the positive terminal 101a is disposed in the center of a top surface formed in a circle, and the negative terminal 101b is disposed in the circumference portion of the positive terminal 101a. Each of the plurality of battery cells 101 may be connected to each of the plurality of bus bars through a cell connector 101c, 101d.

The first bus bar 150 has a straight bar shape. The first bus bar 150 is disposed between the two first cell arrays 102. The first bus bar 150 is connected to the positive terminal of the plurality of battery cells 101 included in the first cell array 102 disposed in one side, and is connected to the negative terminal of the plurality of battery cells 101 included in the first cell array 102 disposed in the other side.

The first bus bar 150 is disposed between the plurality of first cell arrays 102 disposed in the first cell group 105 and the third cell group 107.

The second bus bar 152 connects the first cell array 102 and the second cell array 103 in series. The second bus bar 152 includes a first connecting bar 154 connected to the first cell array 102 and a second connecting bar 156 connected to the second cell array 103. The second bus bar 152 is disposed perpendicular to the first connecting bar 154. The second bus bar 152 includes an extension portion 158 that extends from the first connecting bar 154 and is connected to the second connecting bar 156.

The first connecting bar 154 may be connected to different electrode terminals of the second connecting bar 156 and the battery cell. Referring to FIG. 12, the first connecting bar 154 is connected to the positive terminal 101a of the battery cell 101 included in the first cell array 102, and the second connecting bar 156 is connected to the negative terminal 101b of the battery cell 101 included in the second cell array 103. However, this is just an embodiment and it is possible to be connected to opposite electrode terminal.

The first connecting bar 154 is disposed in one side of the first cell array 102. The first connecting bar 154 has a straight bar shape extending in the length direction of the battery module. The extension portion 158 has a straight bar shape extending in the direction in which the first connecting bar 154 extends.

The second connecting bar 156 is disposed perpendicular to the first connecting bar 154. The second connecting bar 156 has a straight bar shape extending in the width direction (w+, w-) of the battery module. The second connecting bar 156 may be disposed in one side of the plurality of battery cells 101 included in the second cell array 103. The second connecting bar 156 may be disposed between the plurality of battery cells 101 included in the second cell array 103. The second connecting bar 156 extends in the width direction (w+, w-) of the battery module, and is connected to the battery cell 101 disposed in one side or both sides.

The second connecting bar 156 includes a second-first connecting bar 156a and a second-second connecting bar 156b spaced apart from the second-first connecting bar 156a. The second-first connecting bar 156a is disposed between the plurality of battery cells 101, and the second-second connecting bar 156b is disposed in one side of the plurality of battery cells 101.

The third bus bar 160 connects in series the two second cell arrays 103 spaced apart from each other. The third bus bar 160 includes a first vertical bar 162 connected to one cell array among the plurality of second cell arrays 103, a second vertical bar 164 connected to the other cell array among the plurality of second cell arrays 103, and a horizontal bar 166 which is disposed between the plurality of second cell arrays 103 and connected to the first vertical bar 162 and the second vertical bar 164. The first vertical bar 162 and the second vertical bar 164 may be symmetrically disposed with respect to the horizontal bar 166.

A plurality of second vertical bars 164 may be disposed to be spaced apart from each other in the length direction (l+, l-) of the battery module. Referring to FIG. 12, a second-first vertical bar 164a, and a second-second vertical bar 164b which is spaced apart from the second-first vertical bar 164a in the length direction of the battery module may be included.

The first vertical bar 162 or the second vertical bar 164 may be disposed parallel to the second connecting bar 156 of the second bus bar 152. The battery cell 101 included in the second cell array 103 may be disposed between the first vertical bar 162 and the second connecting bar 156. Similarly, the battery cell 101 included in the second cell array 103 may be disposed between the second vertical bar 164 and the second connecting bar 156.

The first battery module 100a includes a fourth bus bar 170 connected to the second battery module 100b included in the same battery pack 10, and a fifth bus bar 180 connected to one battery module included in other battery pack 10.

The fourth bus bar 170 is connected to the second battery module 100b which is another battery module included in the same battery pack 10. That is, the fourth bus bar 170 is connected to the second battery module 100b included in the same battery pack 10 through a high current bus bar 196 described below.

The fifth bus bar 180 is connected to other battery pack 10. That is, the fifth bus bar 180 may be connected to a battery module included in other battery pack 10 through a power line 198 described below.

The fourth bus bar 170 includes a cell connecting bar 172 which is disposed in one side of the first cell array 102, and connects in parallel the plurality of battery cells 101 included in the first cell array 102, and an additional connecting bar 174 which is vertically bent from the cell connecting bar 172 and extends along the end wall of the second frame 130.

The cell connecting bar 172 is disposed in the second sidewall 136 of the second frame 130. The cell connecting bar 172 may be disposed to surround a portion of the outer circumference of the second sidewall 136. The additional connecting bar 174 is disposed outside the second end wall 138 of the second frame 130.

The additional connecting bar 174 includes a connecting hanger 176 to which the high current bus bar 196 is connected. The connecting hanger 176 is provided with a groove 178 opened upward. The high current bus bar 196 may be seated on the connecting hanger 176 through the groove 178. The high current bus bar 196 may be fixedly disposed in the connecting hanger 176 through a separate fastening screw while seated on the connecting hanger 176.

The fifth bus bar 180 may have the same configuration and shape as the fourth bus bar. That is, the fifth bus bar 180 includes a cell connecting bar 182 and an additional connecting bar 184. The additional connecting bar 184 of the fifth bus bar 180 includes a connecting hanger 186 to which a terminal 198a of the power line 198 is connected. The connecting hanger 186 is provided with a groove 188 into which the terminal 198a of the power line 198 is inserted.

The sensing substrate 190 is electrically connected to a plurality of bus bars disposed inside the first battery module 100a. The sensing substrate 190 may be electrically connected to each of the plurality of first bus bars 150, the plurality of second bus bars 152, the third bus bar 160, and the plurality of fourth bus bars 170, respectively. The sensing substrate 190 is connected to each of the plurality of bus bars, so that information such as voltage and current values of the plurality of battery cells 101 included in the plurality of cell arrays can be obtained.

The sensing substrate 190 may have a rectangular ring shape. The sensing substrate 190 may be disposed between the first cell group 105 and the third cell group 107. The sensing substrate 190 may be disposed to surround the second cell group 106. The sensing substrate 190 may be disposed to partially overlap the second bus bar 152.

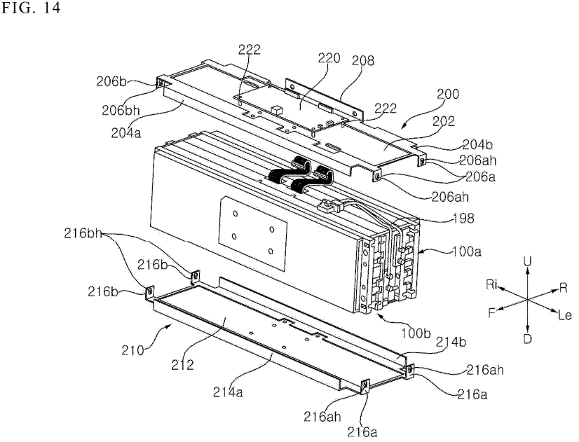

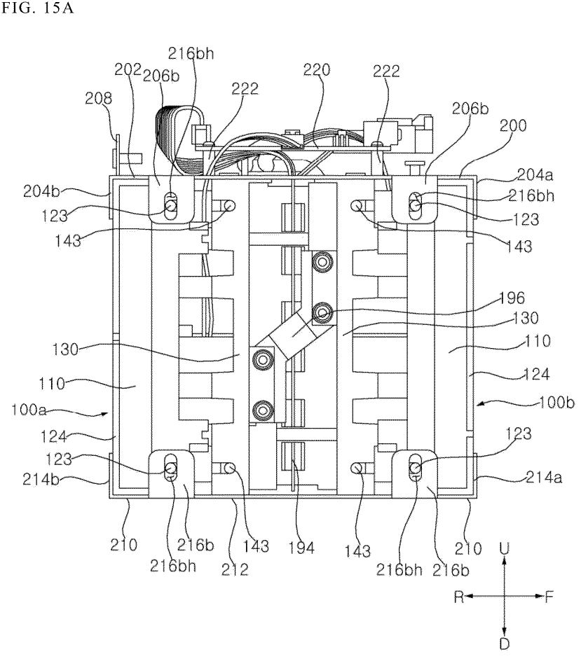

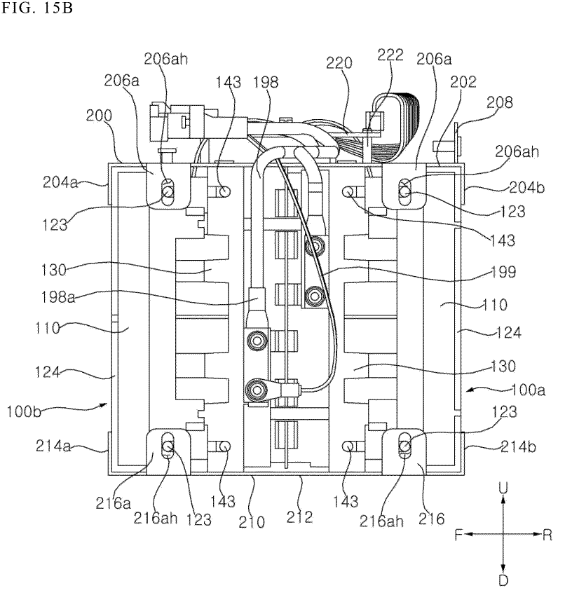

FIG. 14 is a perspective of a battery module and a battery pack circuit substrate according to an embodiment of the present disclosure, FIG. 15A is one side view in a coupled state of FIG. 14, and FIG. 15B is the other side view in a coupled state of FIG. 14.

Referring to FIG. 14 to 15B, the battery pack 10 includes an upper fixing bracket 200 which is disposed in an upper portion of the battery module 100a, 100b and fixes the battery module 100a, 100b, a lower fixing bracket 210 which is disposed in a lower portion of the battery module 100 and fixes the battery modules 100a and 100b, a battery pack circuit substrate 220 which is disposed in an upper side of the upper fixing bracket 200 and collects sensing information of the battery module 100a, 100b, and a spacer 222 which separates the battery pack circuit substrate 220 from the upper fixing bracket 200.

The upper fixing bracket 200 is disposed in an upper side of the battery module 100a, 100b. The upper fixing bracket 200 includes an upper board 202 that covers at least a portion of the upper side of the battery module 100a, 100b, a first upper holder 204a which is bent downward from the front end of the upper board 202 and disposed in contact with the front portion of the battery module 100a, 100b, a second upper holder 204b which is bent downward from the rear end of the upper board 202 and disposed in contact with the rear portion of the battery module 100a, 100b, a first upper mounter 206a which is bent downward from one side end of the upper board 202 and coupled to one side of the battery module 100a, 100b, a second upper mounter 206b which is bent downward from the other side end of the upper board 202 and coupled to the other side of the battery module 100a, 100b, and a rear bender 208 which is bent upward from the rear end of the upper board 202.

The upper board 202 is disposed in the upper side of the battery module 100a, 100b. Each of the first upper mounter 206a and the second upper mounter 206b is disposed to surround the front and rear of the battery module 100a, 100b. Accordingly, the first upper mounter 206a and the second upper mounter 206b may maintain a state in which the first battery module 100a and the second battery module 100b are coupled.

A pair of first upper mounters 206a spaced apart in the front-rear direction are disposed in one side end of the upper board 202. A pair of second upper mounters 206b spaced apart in the front-rear direction are disposed in the other side end of the upper board 202.

The pair of first upper mounters 206a are coupled to the first fastening hole 123 formed in the first battery module 100a and the second battery module 100b. In each of the pair of first upper mounters 206a, a first upper mounter hole 206ah is formed in a position corresponding to the first fastening hole 123. Similarly, the pair of second upper mounters 206b are coupled to the first fastening hole 123 formed in the first battery module 100a and the second battery module 100b, and a second upper mounter hole 206bh is formed in a position corresponding to the first fastening hole 123.

The position of the upper fixing bracket 200 can be fixed in the upper side of the battery module 100a, 100b by the first upper holder 204a, the second upper holder 204b, the first upper mounter 206a, and the second upper mounter 206b. That is, due to the above structure, the upper fixing bracket 200 can maintain the structure of the battery module 100a, 100b.

The upper fixing bracket 200 is fixed to the first frame 110 of each of the first battery module 100a and the second battery module 100b. Each of the first upper mounter 206a and the second upper mounter 206b of the upper fixing bracket 200 is fixed to the first fastening hole 123 formed in the first frame 110 of each of the first battery module 100a and the second battery module 100b.

The rear bender 208 may fix a top cover 230 described below. The rear bender 208 may be fixed to a rear wall 234 of the top cover 230. The rear bender 208 may limit the rear movement of the top cover 230. Accordingly, it is possible to facilitate fastening of the top cover 230 and the upper fixing bracket 200.

The lower fixing bracket 210 is disposed in the lower side of the battery module 100a, 100b. The lower fixing bracket 210 includes a lower board 212 that covers at least a portion of the lower portion of the battery module 100a, 100b, a first lower holder 214a which is bent upward from the front end of the lower board 212 and disposed in contact with the front portion of the battery module 100a, 100b, a second lower holder 214b which is bent upward from the rear end of the lower board 212 and disposed in contact with the rear portion of the battery module 100a, 100b, a first lower mounter 216a which is bent upward from one side end of the lower board 212 and coupled to one side of the battery module 100a, 100b, and a second lower mounter 216b which is bent upward from the other side end of the lower board 212 and coupled to the other side of the battery module 100.

Each of the first lower mounter 216a and the second lower mounter 216b is disposed to surround the front and rear of the battery module 100a, 100b. Accordingly, the first lower mounter 216a and the second lower mounter 216b may maintain the state in which the first battery module 100a and the second battery module 100b are coupled.

A pair of first lower mounters 216a spaced apart in the front-rear direction are disposed in one side end of the lower board 212. A pair of second lower mounters 216b spaced apart in the front-rear direction are disposed in the other side end of the lower board 212.

The pair of first lower mounters 216a are coupled to the first fastening hole 123 formed in the first battery module 100a and the second battery module 100b. In each of the pair of first lower mounters 216a, a first lower mounter hole 216ah is formed in a position corresponding to the first fastening hole 123. Similarly, the pair of second lower mounters 216b are coupled to the first fastening hole 123 formed in the first battery module 100a and the second battery module 100b, and a second lower mounter hole 216bh is formed in a position corresponding to the first fastening hole 123.

The lower fixing bracket 210 is fixed to the first frame 110 of each of the first battery module 100a and the second battery module 100b. Each of the first lower mounter 216a and the second lower mounter 216b of the lower fixing bracket 210 is fixed to the first fastening hole 123 formed in the first frame 110 of each of the first battery module 100a and the second battery module 100b.

The battery pack circuit substrate 220 may be fixedly disposed in the upper side of the upper fixing bracket 200. The battery pack circuit substrate 220 is connected to the sensing substrate 190, the bus bar, or a thermistor 224 described below to receive information of a plurality of battery cells 101 disposed inside the battery pack 10. The battery pack circuit substrate 220 may transmit information of the plurality of battery cells 101 to the main circuit substrate 34a described below.

The battery pack circuit substrate 220 may be spaced apart from the upper fixing bracket 200 upward. A plurality of spacers 222 are disposed, between the battery pack circuit substrate 220 and the upper fixing bracket 200, to space the battery pack circuit substrate 220 upward from the upper fixing bracket 200. The plurality of spacers 222 may be disposed in an edge portion of the battery pack circuit substrate 220.

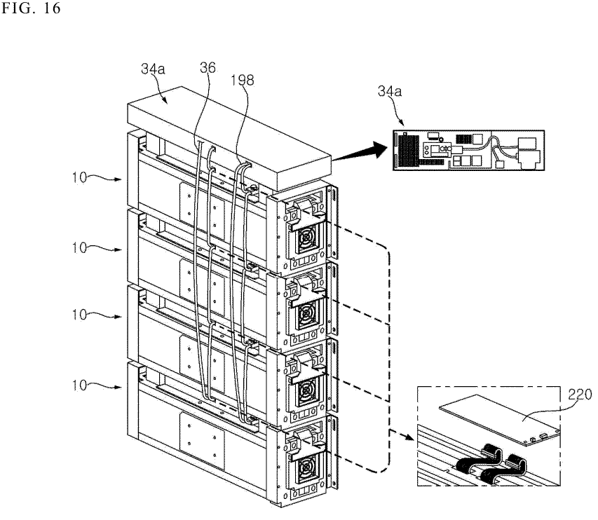

FIG. 16 is a diagram for explaining a connection between the battery pack and the battery management system according to an embodiment of the present disclosure.

Referring to FIG. 16, the battery 35 that stores received electrical energy in a DC form or outputs the stored electrical energy may include a plurality of battery packs 10. Each battery pack 10 includes a plurality of battery cells 101 connected in series and parallel.

The battery pack 10 may include battery modules 100a and 100b in which the plurality of battery cells 101 are connected in series and in parallel, and the battery modules 100a and 100b may be electrically connected to each other.

The battery cells 101 may be connected in series to increase voltage, and may be connected in parallel to increase capacity. In order to increase both the voltage and the capacity, the battery cells 101 may be connected in series and parallel.

Meanwhile, the battery management system 34 for monitoring the state information of the battery 35 includes a battery pack circuit boards 220 which are disposed in each of the plurality of battery packs 10, and obtain state information of the plurality of battery cells 101 included in each battery pack 10, and a main circuit board 34a which is connected to the battery pack circuit boards 220 by a communication line 36, and receives the state information obtained from each battery pack 10 from the battery pack circuit boards 220.

The energy storage system 1 according to an embodiment of the present disclosure includes the battery 35 that stores the received electrical energy in the form of direct current, or outputs the stored electrical energy, the power conditioning system 32 for converting an electrical characteristic so as to charge or discharge the battery 35, and the battery management system 34 for monitoring the state information of the battery 35. The battery 35 includes a plurality of battery packs 10 respectively including a plurality of battery cells 101, and the battery management system 34 includes battery pack circuit boards 220 which is disposed in each of the plurality of battery packs 10 and obtains state information of a plurality of battery cells 101 included in each battery pack 10, and a main circuit board 34a which is connected to the battery pack circuit boards 220 by a communication line and receives state information obtained from each battery pack 10 from the battery pack circuit boards 220.

According to an embodiment of the present disclosure, by separately designing the control circuit 34a including a configuration for managing the battery 35 (particularly a configuration for safety control) from the battery cell sensing circuit 220, it is possible to perform the main function of the battery management system 34 and protect the control circuit 34a that manages the plurality of battery packs 10.

In the battery management system 34, a circuit composed of main components including the microcomputer unit 1780 among circuits for safety control may be separately configured. For example, when four battery packs 10 are connected, the battery management system 34 may be designed with one control circuit unit block 34a including the microcomputer unit 1780, and four battery unit blocks 220.

When the battery pack 10 is short-circuited due to an internal problem, the battery unit block 220 directly connected to the battery cell 101 may be damaged. However, the safety control circuit 34a is designed independently and can be protected without damage.

In addition, since the control circuit 34a and the battery cell sensing circuit 220 are separately configured, each circuit board 34a, 220 can be made smaller.

Meanwhile, the state information transmitted from the battery pack circuit boards 220 to the main circuit board 34a may include at least one of current, voltage, and temperature data. In addition, some of the state information may be measured by a sensor mounted in the main circuit board 34a.

The battery pack circuit boards 220 are sensing and interface boards for voltage, current, and temperature of the battery cells 101. In the battery pack circuit boards 220, a component for obtaining voltage, current, and temperature data of a plurality of battery cells 101 and an interface component for transmitting the obtained data to the main circuit board 34a may be mounted. The voltage, current, and temperature data of the plurality of battery cells 101 may be directly obtained from a sensor mounted in the battery pack circuit boards 220, or may be transmitted to the battery pack circuit substrates 220 from a sensor disposed in the battery cell 101 side.

The plurality of battery packs 10 are connected in series by the power line 198. The power line 198 is connected to the main circuit board 34a. That is, the plurality of battery packs 10 and the main circuit board 34a are connected by the power line 198, and the voltages of the plurality of battery packs 10 are combined and applied to the main circuit board 34a. For example, a plurality of 4 kWh battery packs may be connected in series and disposed inside the casing 12. Two 4 kWh battery packs 10 may be connected to implement a combination 8 kWh, three 4 kWh battery packs 10 may be connected to implement a combination 12 kWh, and four 4 kWh battery packs 10 may be connected to implement a combination 16 kWh.

Two battery modules 100a and 100b may be combined to form a battery module assembly 100, and the battery pack circuit board 220 may be disposed in an upper portion of the battery module assembly 100.

Meanwhile, the power conditioning system 32 for converting electrical characteristics for charging or discharging the battery 35 may be disposed in the upper side of the main circuit board 34a.

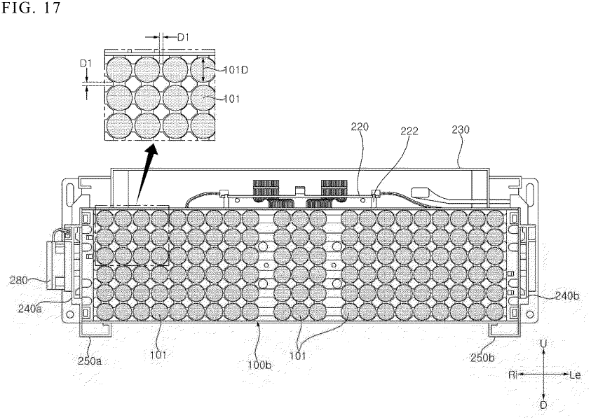

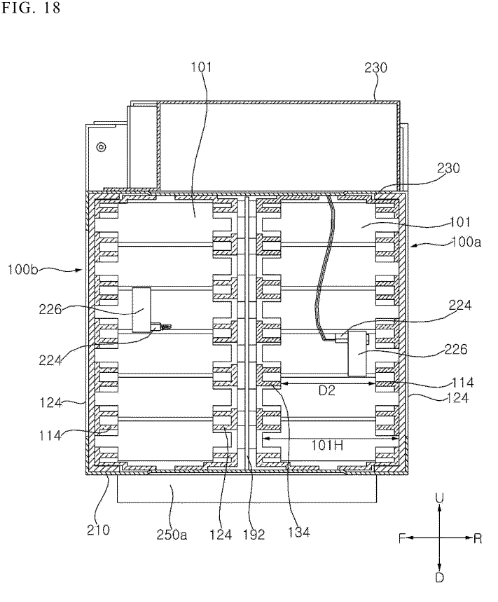

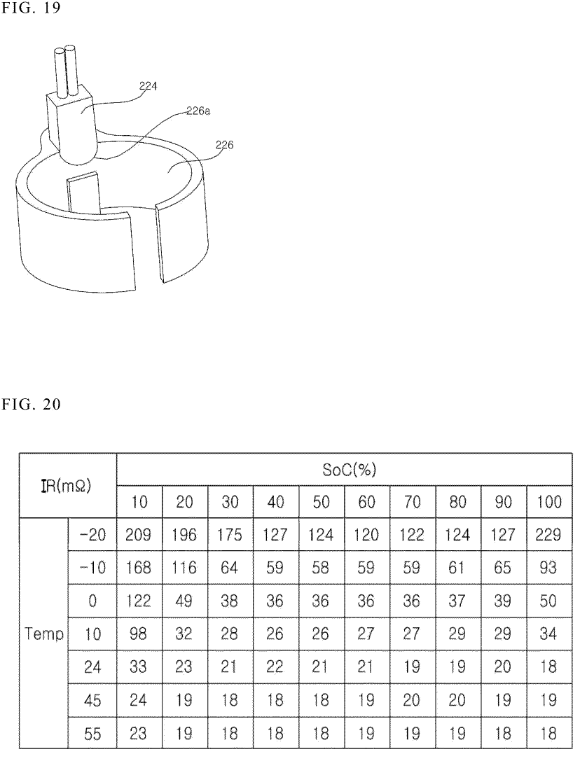

FIG. 17 is a cross-sectional view of a battery pack according to an embodiment of the present disclosure, FIG. 18 is a cross-sectional view for explaining a disposition of battery cells inside a battery pack, FIG. 19 is a perspective view of a thermistor according to an embodiment of the present disclosure.

Hereinafter, a structure for heat dissipation of the battery pack will be described with reference to FIGS. 17 to 19.

Referring to FIG. 17, a plurality of battery cells 101 are spaced apart from each other in four directions which are perpendicular to each other. Referring to FIG. 17, a plurality of battery cells 101 are spaced apart from each other in up, down, left, and right directions.

The disposition of the plurality of battery cells 101 is fixed by the second fixing protrusion 134 of the second frame 130 and the first fixing protrusion 114 of the first frame 110.

Referring to FIG. 17, a distance D1 between the battery cell 101 and other adjacently disposed battery cell 101 may be 0.1 to 0.2 times a diameter 101D of the battery cell 101. An air flow may be formed between the spacing of the plurality of battery cells 101 by the operation of the cooling fan 280.

Referring to FIG. 18, a distance D2 between the second fixing protrusion 134 of the second frame 130 and the first fixing protrusion 114 of the first frame 110 may be 0.5 to 0.9 times the height 101H of the battery cell 101. Accordingly, the area in which the outer circumference of the battery cell 101 is in contact with the flowing air can be maximized.

The cooling fan 280 operates to discharge the air inside the battery module 100a, 100b to the outside. Accordingly, when the cooling fan 280 operates, external air is supplied to the battery module 100a, 100b through the cooling hole 242a of the side cover 240 where the cooling fan 280 is not disposed. In addition, when the cooling fan 280 operates, the air inside the battery module 100a, 100b may be discharged to the outside through the cooling hole 242a of the side cover 240 in which the cooling fan 280 is disposed.

Referring to FIG. 17, the cover plate 242 of each of the pair of side covers 240a and 240b is disposed to be spaced apart from one side end of the battery module 100a, 100b. The size of the cooling hole 242a is formed smaller than the size of one side surface of the battery module 100a, 100b. Accordingly, the cover plate 242 having the cooling hole 242a formed therein is spaced apart from one side end of the battery module 100a, 100b so that the air introduced through the cooling hole 242a flows to each of the plurality of battery cells 101.

The heat dissipation plate 124 is disposed in a lower portion of each of the plurality of battery cells 101. The heat dissipation plate 124 may be formed of an aluminum material to dissipate heat generated in the battery cell 101 to the outside. Each of the plurality of battery cells 101 may be adhered to the heat dissipation plate 124 through a conductive adhesive solution.

The conductive adhesive solution, which is a bonding solution containing alumina, fixes the heat dissipation plate 124 disposed in a lower portion of the battery cell 101 and transfers heat generated from the battery cell 101 to the heat dissipation plate 124.

In some of the plurality of battery cells 101, a thermistor 224 for measuring the temperature of the battery cell 101, and a mounting ring 226 for fixing the disposition of the thermistor 224 to the outer circumference of the battery cell 101 are disposed. The thermistor 224 may be disposed in the battery cell 101 disposed in a portion where mainly temperature is increased among the plurality of battery cells 101.

The mounting ring 226 has an open ring shape at one side, and forms a mounting groove 226a in which the thermistor 224 is mounted at one side that is not opened. The mounting ring 226 is mounted in the outer circumference of the battery cell 101 to bring the thermistor 224 into contact with the outer circumferential surface of the battery cell 101.

The thermistor 224 is connected to the battery pack circuit substrate 220 through the signal line 199. The thermistor 224 may transmit temperature information detected by the battery cell 101 to the battery pack circuit substrate 220. The battery pack 10 may adjust the rotation speed of the cooling fan 280 based on the temperature information detected from the thermistor 224.

The heat dissipation plate 124 may be disposed to contact one side of the casing 12 described below. The casing 12 is configured to accommodate at least one battery pack 10. Accordingly, the heat dissipation plate 124 may transfer the heat received from the battery cell 101 to the casing 12.

When the temperature of the battery 35 rises to a high temperature and is continuously used, the battery life is reduced. In addition, when the temperature of the battery 35 is used at a low temperature, internal resistance is increased, so that efficiency is lowered and high output is difficult.

Accordingly, according to an embodiment of the present disclosure, charging/discharging of the battery may be controlled based on the temperature of the battery cell 101 sensed by the thermistor 224.

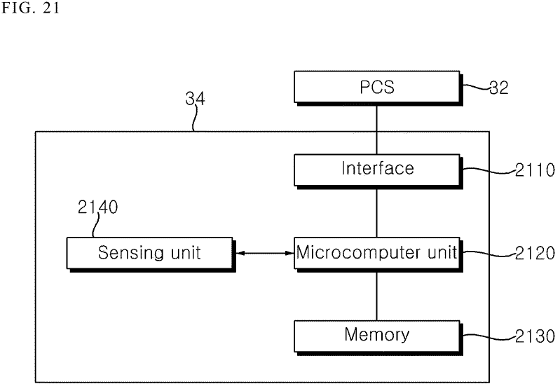

FIG. 20 is a diagram for explaining an internal resistance of the battery, and shows the internal resistance (IR) of the battery cell 101 according to the temperature and the state of charge (SoC).

Referring to FIG. 20, it can be seen that the internal resistance (IR) sharply increases as the temperature decreases.

At a low temperature, the internal resistance (IR) of the battery cell 101 sharply increases, and the efficiency is lowered, which affects the stabilization of the system.

Since the internal resistance (IR) is high at low temperature, the amount of heat increases even if a small current is applied. Therefore, it is possible to have an effect on heating with low current power.

The energy storage system 1 according to an embodiment of the present disclosure includes a battery 35 that stores the received electrical energy in the form of direct current or outputs the stored electrical energy, and a battery management system 34 that controls the battery 35, and may control charging and discharging of the battery 35 based on the temperature of the battery 35.

For example, at a low temperature, the battery management system 34 starts charging with a low current, and when the temperature rises to a certain level or higher due to heat generated by an increase in internal resistance, the charging current may be increased.

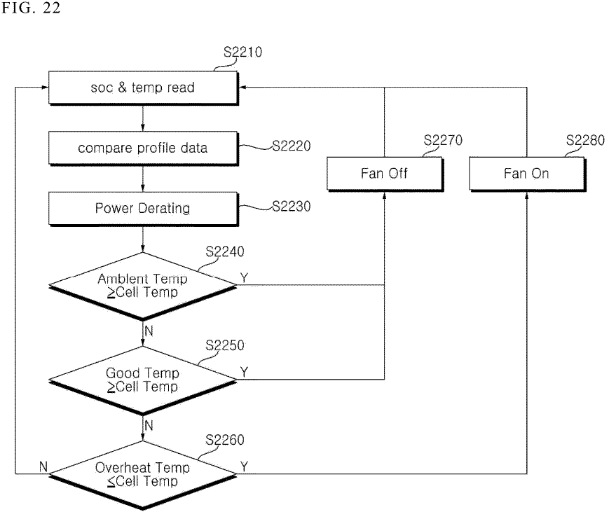

FIG. 21 is a block diagram of an energy storage system according to an embodiment of the present disclosure, and shows an internal block of the battery management system 34.

Referring to FIG. 21, the battery management system 34 according to an embodiment of the present disclosure includes a sensing unit 2140 including a sensor for measuring the temperature of the battery 35, a memory 2130 that stores data necessary for the operation of the battery management system 34, and a microcomputer unit 2120 that controls the overall operation of the battery management system 34.

The sensor for measuring the temperature of the battery 35 may be a thermistor 224 disposed in the outer circumference of at least one of the plurality of battery cells 101. In addition, the temperature of the battery 35 may be based on at least one of temperature data sensed by the thermistor 224. For example, the temperature of the battery 35 may be an average value or a maximum value of temperature data sensed by the thermistor 224.

The memory 2130 may store a derating table for charging and a derating table for discharging.

When charging the battery 35, the microcomputer unit 2120 may control the C-rate based on the temperature of the battery and the derating table for charging.

In addition, when discharging the battery 35, the microcomputer unit 2120 may control the C-rate based on the temperature of the battery and the derating table for discharging.

The C-rate is called as a charging rate, a discharging rate, a charging/discharging rate, or the like, is a unit for setting the current value during charging/discharging, and may be calculated according to the formula of C-rate (A) = charge/discharge current (A)/rated capacity of the battery.

If the battery is used in a high temperature state, the lifespan will be shortened. Therefore, it is necessary to drop the temperature from the high temperature to a stable section.

When the battery is used in a low temperature state, efficiency problems occur, because the capacity is severely reduced due to the increase in internal resistance during discharging. In addition, when the battery is used in a low temperature state, a problem occurs in terms of system stabilization. Therefore, it is necessary to raise the temperature from the low temperature to the stable section.

When charging at a high C-rate in a low temperature state (e.g., -10° C. to 0° C.), the temperature difference between cells is widened and yellow color phenomenon occurs in a negative electrode due to Li plating during long-term use, and lithium ion is metalized to gradually grow, thereby eventually causing a short circuit with a positive electrode. However, a low current charging of 0.1 C or less can be accomplished even in a low temperature state.

According to an embodiment of the present disclosure, the battery management system 34 is provided with two derating tables for charging and discharging, and utilizes it for dedicated power derating during charging or discharging, thereby achieving an optimized control for battery characteristics during charging and battery characteristics during discharging.

For example, the microcomputer 2120 prevents lithium plating during low-temperature charging, increases battery efficiency during low-temperature discharging, and can control the C-rate according to temperature change so as to enable to extend the lifespan by maintaining the appropriate temperature, during high-temperature charging and discharging.

In addition, the derating table for discharging includes more C-rate levels than the derating table for charging, so that the C-rate can be more precisely controlled.

Meanwhile, the microcomputer unit 2120 controls the battery temperature to maintain a stable operating temperature section during charging and discharging, thereby extending the life of the battery 35, and improving stability and reliability of the energy storage system 1.

In addition, the energy storage system 1 battery power derating requires more precise C-rate control for discharge and high temperature. According to an embodiment of the present disclosure, it is possible to respond to both a low-temperature situation and a high-temperature situation.

According to an embodiment of the present disclosure, in order to reduce the risk of lithium plating at a low temperature, low current heating is used by controlling the C-rate to be low, and when the temperature is higher than or equal to a certain temperature, the C-rate is increased.

As described above with reference to FIGS. 1A 1B-3A 3B 4–14 15A 15B 16, the battery 35 includes a plurality of battery packs 10, and a cooling fan 280 may be disposed in one side of each battery pack 10.

According to an embodiment of the present disclosure, the power derating and the cooling fan 280 that adjust the C-rate according to the temperature may be used to prevent overheating at a high temperature. The microcomputer unit 2120 may drive the cooling fan 280 during charging/discharging or in an idle state after charging/discharging. In addition, when the temperature of the battery is an overheating reference value or higher, the cooling fan may be controlled to be turned on.

The battery management system 34 reads the battery temperature from the thermistor 224, and may maintain an appropriate temperature by using power derating and the cooling fan 280.

Meanwhile, the microcomputer unit 2120 may turn off the cooling fan 280, when the temperature of the battery 35 is lower than or equal to a stable temperature reference value and the cooling fan 280 is a turn-on state. For example, when the temperature of the battery 35 is lower than or equal to the stable temperature reference value, or more precisely, the upper limit reference value of the stable section, it is not necessary to operate the cooling fan 280, so that the efficiency can be improved without driving the cooling fan 280.

According to an embodiment of the present disclosure, safety may be further enhanced by maintaining a safe temperature range through power derating.

Further, according to an embodiment of the present disclosure, it is possible to increase the battery life by maintaining an appropriate temperature state.

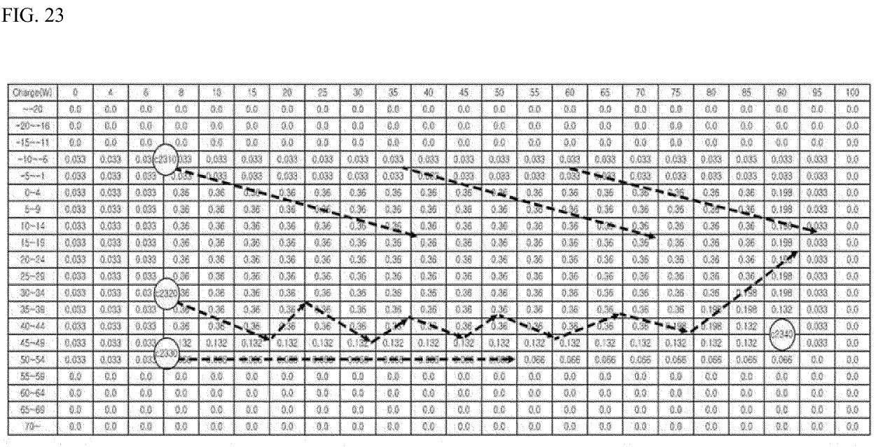

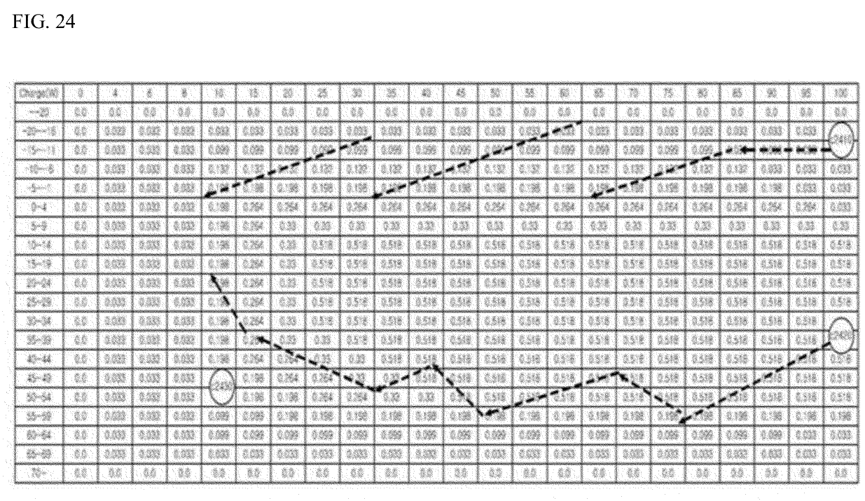

Meanwhile, the memory 2230 may store tables that scale C-rate based on temperature and SOC according to a charge/discharge state. The derating table for charging and the derating table for discharging may be configured of C-rate values corresponding to the temperature of the battery 35 and the state of charge of the battery 35 (refer to FIGS. 23 and 24).

The microcomputer unit 2120 may calculate the state of charge (SOC) of the battery 35, and may control the charging and discharging of the battery, based on the calculated state of charge, the temperature of the battery 35, the derating table for charging, and the derating table for discharging.

The microcomputer 2120 may calculate the state of charge (SOC) by using a well-known method such as a battery capacity counting method, an OCV measurement method, and an impedance measurement method.

The microcomputer unit 2120 may induce the temperature to change within a stable section range, by controlling the power by changing the C-rate, at low and high temperatures.

Self-heating can be used as an internal resistance for low current charging (e.g., 0.1c or less) to prevent lithium plating at low temperatures. At a low temperature, the microcomputer unit 2120 increases the temperature by performing charging and discharging by lowering the current with the change of C-rate.

According to an embodiment of the present disclosure, at 0° C. or less, for safety, without fast charging, the temperature is raised to a stable section by low current charging. Thereafter, when the temperature rises to an appropriate temperature, the microcomputer unit 2120 increases the C-rate to perform highspeed charging.

During low-temperature discharge, the efficiency decreases due to an increase in internal resistance. At this time, if it goes up to the stable section, high output can be produced. Therefore, the efficiency decreases due to an increase in internal resistance during low-temperature discharge. At this time, if it goes up to the stable section, high output can be produced. The microcomputer unit 2120 may control the C-rate so that the temperature rises to a stable section even during low-temperature discharge. Accordingly, it is possible to compensate, to some extent, the decrease in capacity during low current operation at low temperature.

When charging the battery at a high C-rate, a phenomenon that quickly rises to a high temperature of a certain level or higher may occur. When overheating occurs, the microcomputer 2120 may control the cooling fan 280 to quickly cool the heat.

According to an embodiment of the present disclosure, battery efficiency can be improved by raising the temperature from a low temperature state to an appropriate temperature state by a heating method, and can prevent Li-plating when charging at a low temperature.

In addition, according to an embodiment of the present disclosure, it is possible to provide high output and increase reliability while maintaining a stable state.

Meanwhile, according to an embodiment of the present disclosure, it is possible to minimize the influence of the characteristic change during charging/discharging switching. In order to prevent conversion from charging to discharging or from discharging to charging in a high temperature state, according to the state of the state of charge, the C-rate may be previously adjusted so that charging and discharging can be switched in a better state, depending on the state of charge state.

For example, when the battery 35 is charged above the charging reference value, there is high probability of being converted to a discharge state. Therefore, in preparation for conversion to a discharge, the C-rate may be previously lowered. In addition, since it is more dangerous to switch to discharging in a high-temperature environment, when the battery 35 is charged, the microcomputer 2120 may lower the C-rate, when the temperature and the state of charge of the battery 35 are greater than or equal to a charging reference value.

For example, when the battery 35 is discharged with a discharge reference value or higher, there is high probability of being converted to a charged state. Therefore, in preparation for conversion to charging, the C-rate may be previously lowered. Accordingly, when the battery is discharged, the microcomputer 2120 may lower the C-rate when the state of charge of the battery 35 is less than or equal to the discharge reference value.

Meanwhile, according to an embodiment of the present disclosure, the battery temperature may be managed in consideration of the outside air temperature data.

For example, a power conditioning system 32 may be provided with a sensor for measuring the outside air temperature, or may acquire outside air temperature data by communicating with an external device.

The power conditioning system 32 may transmit outside air temperature data to the battery management system 34.

The battery management system 34 may further include an interface 2110 for receiving outside air temperature data from the power conditioning system 32. For example, the interface 2110 may receive the outside air temperature data through CAN communication.

The microcomputer unit 2120 may control the cooling fan 280 based on the received outside air temperature data.

For example, when the temperature of the battery 35 is equal to or less than the outside air temperature, if the cooling fan 280 is in a turn-on state, the microcomputer unit 2120 may turn off the cooling fan 280. That is, if the outside air temperature is higher than the temperature of the battery 35, even if the cooling fan 280 is rotated, the effect due to the inflow of outside air may be low or the temperature may be rather increased. Therefore, when the outside air is hotter, the efficiency can be improved without driving the cooling fan 280.

In addition, the above-described battery 35, the battery management system 34, and the power conditioning system 32 may be disposed inside one casing 12. The battery 35, the battery management system 34, and the power conditioning system 32 integrated in one casing 12 in this way can effectively store and convert power.

According to an embodiment of the present disclosure, since the charging current is controlled by comparing the current temperature of the battery with a preset temperature in the battery charging mode, it has the effect of preventing the battery from overheating, and solving the problem of reducing the durability of the system caused by the heat of the battery, and the problem of abnormal function operation.

Meanwhile, as described with reference to FIG. 16, the battery management system 34 may include battery pack circuit boards 220 which are disposed in each of the plurality of battery packs 10 and obtain state information of the plurality of battery cells 101 included in each battery pack 10, and a main circuit board 34a which is connected to the battery pack circuit boards 220 by a communication line, and receives state information obtained from each battery pack 10 from the battery pack circuit boards 220. Here, the microcomputer unit 2120 and the memory 2130 may be mounted in the main circuit board 34a. The plurality of battery packs 10 may be connected in series by a power line 198, and the power line 198 may be connected to the main circuit board 34a. Accordingly, when the battery pack 10 is short-circuited due to an internal problem, even if the battery pack circuit boards 220 directly connected to the battery cell 101 are damaged, the microcomputer unit 2120 of the independently designed main circuit board 34a and the memory 2130 may be protected without damage.

Meanwhile, the thermistor 224 and the battery pack circuit board 220 included in each of the plurality of battery packs 10 may be connected by wire.

As described above, the energy storage system 1 according to an embodiment of the present disclosure includes a battery 35 and a battery management system 34 for controlling the battery 35. The battery 35 includes a plurality of battery packs 10 that respectively includes a plurality of battery cells 101 and a cooling fan 280. The battery management system 34 includes a sensing unit 2140 including a sensor for measuring the temperature of the battery 35, and a microcomputer unit 2120 that changes the C-rate according to the temperature change of the battery 35, and turns on the cooling fan 280 when the temperature of the battery 35 is higher than or equal to the overheating reference value. Accordingly, overheating of the battery 35 can be more effectively prevented.

In addition, the battery management system 34 may further include a memory 2130 in which a derating table for charging and a derating table for discharging are stored.

The microcomputer unit 2120 calculates the state of charge (SOC) of the battery 35, and may control the charging and discharging of the battery 35 based on the calculated state of charge, the temperature of the battery 35, the derating table for charging, and the derating table for discharging. The temperature of the battery 35 may be based on at least one of temperature data sensed by the thermistor 224. For example, the temperature of the battery 35 may be an average value or a maximum value of temperature data sensed by the thermistor 224.

The energy storage system 1 according to an embodiment of the present disclosure further includes a power conditioning system 32. The power conditioning system 32 may transmit outside air temperature data to the battery management system 34.

The battery management system 34 may further include an interface 2110 for receiving outside air temperature data from the power conditioning system 32. When the temperature of the battery 35 is equal to or less than the outside air temperature, if the cooling fan 380 is in a turn-on state, the microcomputer unit 2120 may turn off the cooling fan 380.

In addition, when the temperature of the battery 35 is equal to or less than the stable temperature reference value, and if the cooling fan 280 is in a turn-on state, the microcomputer unit 2120 may turn off the cooling fan 280.

FIG. 22 is a flowchart illustrating an operating method of an energy storage system according to an embodiment of the present disclosure.

Referring to FIG. 22, the microcomputer 2120 periodically reads the state of charge and the temperature data of the battery 35 (S2210). In addition, the microcomputer unit 2120 also periodically reads the charge/discharge state.

The memory 2130 stores a power control table based on the state of charge (SOC) of the battery 35 and the temperature of the battery 35. The power control table may include two tables for charging and discharging. That is, the memory 2130 may store a derating table for charging and a derating table for discharging.

During charging, the microcomputer 2120 may compare the state of charge and temperature data of the battery 35 with the profile of the derating table for charging (S2230).

In addition, when discharging, the microcomputer 2120 may compare the state of charge and temperature data of the battery 35 with the profile of the derating table for discharging (S2230).

Meanwhile, the microcomputer 2120 may load a profile of the derating table for charging and the derating table for discharging from the memory 2130 in initialization.

The microcomputer 2120 compares the current data with the data of the derating table (S2220), and performs derating for controlling the C-rate (S2230).

Meanwhile, after derating (S2230), according to whether the overheating reference value is reached (S2260), the cooling fan 280 may be driven (S2280). Accordingly, it is possible to lower the temperature more quickly in case of overheating.

Meanwhile, when the temperature of the battery 35 is equal to or less than the outside air temperature (S2240), if the cooling fan 280 is in a turn-on state, the microcomputer unit 2120 may turn off the cooling fan 280 (S2270). That is, if the outside air temperature is higher than the temperature of the battery 35, even if the cooling fan 280 is rotated, the effect due to the inflow of outside air may be low or the temperature may be rather increased. Therefore, when the outside air is hotter, the efficiency can be improved without driving the cooling fan 280.

Meanwhile, when the temperature of the battery 35 is less than or equal to the stable temperature reference value (good Temp) (S2250), if the cooling fan 280 is in a turn-on state, the microcomputer unit 2120 may turn off the cooling fan 280 (S2270). For example, if it is less than or equal to the stable temperature reference value, it is not necessary to drive the cooling fan 280. Thus, the efficiency can be improved without driving the cooling fan 280.

FIGS. 23 and 24 are diagrams for explaining an operating method of an energy storage system according to an embodiment of the present disclosure.

FIG. 23 illustrates a derating table for charging and charging power derating processes, and FIG. 24 illustrates a derating table for discharging and discharging power derating processes.

In FIGS. 23 and 24, y-axis represents a battery cell temperature, x-axis represents the state of charge (SoC), and each cell represents the C-rate corresponding to the battery cell temperature and the state of charge.

Referring to FIG. 23, in the derating table for charging, it is exemplified that C-rate is 0, 0.033, 0.066, 0.132, and 0.36 levels, and the maximum C-rate is 0.36 C. Referring to FIG. 23, when the C-rate is set to 0 in the low-temperature section and the high-temperature section, charging is not performed.

Meanwhile, the microcomputer unit 2310 may control battery charging to operate in a section in which safety is ensured, e.g. the battery temperature is 10 degrees to 40 degrees. Accordingly, it is possible to extend battery life and improve efficiency by securing safety.

The first case c2310 exemplifies a low-temperature charging case. Referring to the first case c2310, it is charged with 0.033 to gradually increase the temperature, reaches a stable section to be charged with high output.

The second case c2320 exemplifies a charging case in a section of 30 degrees or higher. Referring to the second case c2320, if overheating of 45° C. or higher occurs when it is charged with a maximum C-rate 0.36 C high output, derating is performed with 0.132 C. Thus, the temperature is lowered.

Meanwhile, when overheating of 45° C. or higher occurs, the cooling fan 280 is driven to further shorten the time to enter the stable section.

The third case c2330 exemplifies a high-temperature charging case in a state where the temperature is 55 degrees or higher and the outside air temperature is high. In a state where the outside air temperature and the battery temperature are high, low-power charging may proceed for stability.

The fourth case c2340 exemplifies a high-temperature section of 80% or more of the state of charge during charging. In the fourth case c2340, a derating level (e.g., 0.132) may be added compared to a state in which any one of a state of charge and a temperature is small, as a step-by-step derating for minimizing a temperature rise when the discharging mode is switched.

Referring to FIG. 24, in the derating table for discharging, it is exemplified that the C-rate is 0, 0.033, 0.066, 0.132, 0.264, 0.33, and 0.518 levels, and the maximum C-rate is 0.518 C. Referring to FIGS. 23 and 24, it can be seen that there are fewer sections in which the C-rate is designated as 0 during discharge, and the number of C-rate levels is larger during discharge. In addition, there occurs a difference even in the maximum C-rate.

As described above, according to an embodiment of the present disclosure, it is possible to perform optimized control with different derating tables during charging and discharging.

Meanwhile, the microcomputer unit 2310 may control battery discharge to operate in a section in which safety is secured, e.g., the battery temperature is 10 degrees to 35 degrees (or 10 to 40 degrees). Accordingly, it is possible to extend battery life and improve efficiency by securing safety.

The first case c2410 exemplifies a low-temperature discharge case. Referring to the first case c2310, a stepwise discharge occurs by dividing into 4 steps with a higher C-rate than during charging.

The second case c2420 exemplifies a discharge case in a section of 30 degrees or higher. Referring to the second case c2420, when it is discharged with a high output and overheating of 45° C. or higher occurs, derating is performed with 0.198 C. Thus, the temperature is lowered.

Meanwhile, when overheating of 45° C. or higher occurs, the cooling fan 280 is driven to further shorten the time to enter the stable section.

The third case c2430 exemplifies a section in which the state of charge is 35% or less during discharging. In the fourth case c2430, a derating level (e.g., 0.099) may be added to de-rate stepwise, as a step-by-step de-rating for minimizing a temperature rise when the charging mode is switched.

According to at least one of the embodiments of the present disclosure, safety and efficiency may be improved by operating in a safe temperature range for the battery.

In addition, according to at least one of the embodiments of the present disclosure, battery life may be improved while maintaining an appropriate temperature state.

In addition, according to at least one of the embodiments of the present disclosure, high output is possible while maintaining a stable state.

In addition, according to at least one of the embodiments of the present disclosure, safety may be enhanced by a multi-safety design.

In addition, according to at least one of the embodiments of the present disclosure, it is possible to effectively dissipate heat from the battery.

While the present invention has been particularly shown and described with reference to exemplary embodiments thereof, it will be understood by those of ordinary skill in the art that various changes in form and detail may be made herein without departing from the spirit and scope of the present invention as defined by the following claims and such modifications and variations should not be understood individually from the technical idea or aspect of the present invention.

What is claimed is:

1. An energy storage system comprising:
a battery configured to store received electrical energy in a form of direct current, and to output the stored electrical energy; and
a battery management system configured to control the battery,
wherein the battery management system comprises:
a sensing unit comprising a sensor for measuring a temperature of the battery;
a memory in which a derating table for charging the battery and a derating table for discharging the battery are stored; and
a microcomputer unit configured to control a charging rate (C-rate) based on the temperature of the battery and the derating table for charging when charging the battery, and to control the C-rate based on the temperature of the battery and the derating table for discharging when discharging the battery.

2. The energy storage system of claim 1, wherein the microcomputer unit calculates a state of charge (SOC) of the battery, and
controls charging and discharging of the battery based on the calculated state of charge, the temperature of the battery, the derating table for charging, and the derating table for discharging.

3. The energy storage system of claim 2, wherein the derating table for charging and the derating table for discharging are configured for C-rate values corresponding to the temperature of the battery and the state of charge of the battery.

4. The energy storage system of claim 1, wherein the battery comprises a plurality of battery packs,
wherein a cooling fan is disposed in one side of each battery pack.

5. The energy storage system of claim 4, wherein at least one cooling fan is turned on based on the temperature of the battery being higher than or equal to an overheating reference value.

6. The energy storage system of claim 4, wherein based on the temperature of the battery being lower than or equal to a stable temperature reference value, the at least one cooling fan is turned off, based on the at least one cooling fan being in a turn-on state.

7. The energy storage system of claim 4, further comprising a power conditioning system for transmitting outside air temperature data to the battery management system,
wherein based on the temperature of the battery being lower than or equal to the outside air temperature, the at least one cooling fan is turned off, based on the at least one cooling fan being in a turn-on state.

8. The energy storage system of claim 7, further comprising a casing forming a space in which the power conditioning system and the plurality of battery packs are disposed.

9. The energy storage system of claim 1, wherein the battery comprises a plurality of battery cells,
wherein the sensor for measuring the temperature of the battery is a thermistor disposed in an outer circumference of at least one of the plurality of battery cells,
wherein the temperature of the battery is based on at least one of temperature data sensed by the thermistor.

10. The energy storage system of claim 1, wherein the battery comprises a plurality of battery packs respectively including a plurality of battery cells,
wherein the battery management system comprises:
battery pack circuit boards disposed in each of the plurality of battery packs, and to acquire state information of the plurality of battery cells included in each battery pack; and
a main circuit board connected to the battery pack circuit boards by a communication line, and to receive state information acquired from each battery pack from the battery pack circuit boards.

11. The energy storage system of claim 10, wherein the microcomputer unit and the memory are mounted in the main circuit board.

12. The energy storage system of claim 10, wherein the sensor for measuring the temperature of the battery is a thermistor disposed in an outer circumference of at least one of the plurality of battery cells,
wherein the thermistor included in each of the plurality of battery packs and the battery pack circuit board are connected by a wire.

13. The energy storage system of claim 1, wherein the derating table for discharging includes more C-rate levels than the derating table for charging.

14. The energy storage system of claim 1, wherein the microcomputer unit lowers the C-rate, based on the temperature and the state of charge of the battery being higher than or equal to a charging reference value, during the charging of battery, and
lowers the C-rate, based on the state of charge of the battery being less than or equal to a discharge reference value, during the discharging of battery.

15. An energy storage system comprising:
a battery configured to store received electrical energy in a form of direct current, or to output the stored electrical energy; and
a battery management system configured to control the battery,
wherein the battery comprises a plurality of battery packs respectively comprising a plurality of battery cells and a cooling fan,
wherein the battery management system comprises:
a sensing unit comprising a sensor for measuring temperature of the battery; and
a microcomputer unit configured to change a C-rate according to a temperature change of the battery, and turns on the cooling fan based on the temperature of the battery being equal to or higher than an overheating reference value.

16. The energy storage system of claim 15, wherein the battery management system further comprises a memory in which a derating table for charging and a derating table for discharging are stored,
wherein the microcomputer unit calculates a state of charge (SOC) of the battery, and
controls charging and discharging of the battery based on the calculated state of charge, the temperature of the battery, the derating table for charging, and the derating table for discharging.

17. The energy storage system of claim 15, further comprising a power conditioning system for transmitting outside air temperature data to the battery management system,
wherein based on the temperature of the battery being equal to or lower than the outside air temperature, the cooling fan is turned off, based on the cooling fan being in a turn-on state.

18. The energy storage system of claim 15, wherein based on the temperature of the battery being equal to or lower than a stable temperature reference value, the cooling fan is turned off, based on the cooling fan being in a turn-on state.

19. The energy storage system of claim 15, wherein the sensor for measuring the temperature of the battery is a thermistor disposed in an outer circumference of at least one of the plurality of battery cells,
wherein the temperature of the battery is based on at least one of temperature data sensed by the thermistor.

20. The energy storage system of claim 15, wherein the battery comprises a plurality of battery packs respectively comprising a plurality of battery cells,
wherein the battery management system comprises:
battery pack circuit boards disposed in each of the plurality of battery packs, and to acquire state information of the plurality of battery cells included in each battery pack; and
a main circuit board connected to the battery pack circuit boards by a communication line, and to receive state information acquired from each battery pack from the battery pack circuit boards.
